(19) United States
(12) Patent Application Publication
(10) Pub. No.: US 2021/0256898 A1
(43) Pub. Date: Aug. 19, 2021

(54) LIGHT EMITTING DIODE PACKAGE AND DISPLAY APPARATUS INCLUDING THE SAME

(71) Applicant: SAMSUNG ELECTRONICS CO., LTD., Suwon-si (KR)

(72) Inventor: Kyoungjun KIM, Yongin-si (KR)

(73) Assignee: SAMSUNG ELECTRONICS CO., LTD., Suwon-si (KR)

(21) Appl. No.: 17/060,998

(22) Filed: Oct. 1, 2020

(30) Foreign Application Priority Data
Feb. 18, 2020 (KR) 10-2020-0019991

(51) Int. Cl. G09G 3/32

(52) U.S. Cl. CPC G09G 3/32; G09G 2320/064; G09G 2300/0809

(57) ABSTRACT

A display apparatus includes a plurality of light emitting diode (LED) packages arranged in a matrix on a module substrate and a controller. Each of the plurality of LED packages includes a pixel driving integrated circuit and a first LED chip, a second LED chip, and a third LED chip on the pixel driving integrated circuit. The pixel driving integrated circuit controls, based on a control signal of the controller, a pulse width of current applied to the first, second, and third LED chips at a first current level or at a second current level.

### CROSS-REFERENCE TO RELATED APPLICATION

This application claims priority to Korean Patent Application No. 10-2020-0019991, filed on Feb. 18, 2020, in the Korean Intellectual Property Office, the disclosure of which is incorporated by reference herein in its entirety.

### BACKGROUND

Embodiments of the present disclosure relate to a semiconductor integrated circuit, and more particularly, to a light emitting diode (LED) package and a display apparatus including the same.

LEDs are used as light sources for lighting fixtures and various electronic products. In particular, LEDs are widely used as light sources for various display apparatuses such as televisions (TVs), mobile phones, personal computers (PCs), notebook PCs, and personal digital assistants (PDAs).

Display apparatuses may include a liquid crystal display (LCD) panel and a backlight. However, LED displays, in which, for example, three micro-LED chips form a pixel, have recently been suggested. LED displays do not need a backlight and are thus suitable for high level integration and have excellent light efficiency compared to existing LCD displays. In addition, by changing the arrangement of LED chips, an aspect ratio of a screen may be freely selected and a large-scale screen may be provided.

### SUMMARY

One or more example embodiments provide a light emitting diode (LED) package having enhanced reliability when operating at low luminance, and a display apparatus using the same.

Embodiments are not limited to those mentioned above, and the inventive concept that has not been mentioned will be clearly understood by one of skill in the art from the description below.

According to an aspect of an example embodiment, there is provided a display apparatus including: a module substrate; a plurality of light emitting diode (LED) packages arranged in a matrix on the module substrate; and a controller electrically connected to the plurality of LED packages through the module substrate, wherein each of the plurality of LED packages includes: a package substrate; a pixel driving integrated circuit on the package substrate; and a first LED chip, a second LED chip, and a third LED chip on the pixel driving integrated circuit, and wherein the pixel driving integrated circuit is configured to, based on a control signal of the controller, control a pulse width of current, applied to the first, second, and third LED chips at a first current level, in a first pulse width modulation (PWM) mode or control a pulse width of current, applied to the first, second, and third LED chips at a second current level, in a second PWM mode, the second current level being different from the first current level.

According to an aspect of an example embodiment, there is provided a light emitting diode (LED) package, including: a pixel driving integrated circuit configured to control a pixel using an active matrix; and a first LED chip, a second LED chip, and a third LED chip on the pixel driving integrated circuit and configured to form the pixel, wherein the pixel driving integrated circuit includes: a current regulator configured to, based on frame data, output a first reference current, a second reference current, and a third reference current having variable current levels; and an LED driver configured to generate, based on the first, second, and third reference currents and the frame data, a first driving current for driving the first LED chip, a second driving current for driving the second LED chip, and a third driving current for driving the third LED chip, and wherein the LED driver is further configured to control a pulse width of each of the first, second, and third driving currents based on a gray scale.

According to an aspect of an example embodiment, there is provided a pixel driving integrated circuit for driving a pixel including light emitting diode (LED) chips, the pixel driving integrated circuit including: a deserializer configured to receive serial data from an external controller and extract, from the serial data, frame data for a first pixel; a data storage configured to store the frame data extracted by the deserializer; a current regulator configured to output, in one of a first mode and a second mode, a first reference current, a second reference current, and a third reference current based on the frame data; and an LED driver configured to generate, based on the frame data and the first, second, and third reference currents, a first driving current for driving a first LED chip, a second driving current for driving a second LED chip, and a third driving current for driving a third LED chip, wherein the LED driver is further configured to control luminance of the first, second, and third LED chips by controlling pulse widths of the first, second, and third driving currents, and wherein the current regulator is further configured to output the first, second, and third reference currents at a first current level in the first mode and output the first, second, and third reference currents at a second current level in the second mode, the second current level being lower than the first current level.

According to an aspect of an example embodiment, there is provided a light emitting diode (LED) package including: a first LED chip, a second LED chip, and a third LED chip; and a first pixel driving integrated circuit on or below the first, second, and third LED chips, the first pixel driving integrated circuit being configured to drive the first, second, and third LED chips using an active matrix and pulse width modulation (PWM), wherein the first pixel driving integrated circuit is further configured to provide a driving current at a first current level to the first, second, and third LED chips based on luminance of the first, second, and third LED chips being equal to or greater than a threshold, and configured to provide the driving current at a second current level to the first, second, and third LED chips based on the luminance of the first, second, and third LED chips being less than the threshold.

According to an aspect of an example embodiment, there is provided a display apparatus including: a module substrate; a plurality of light emitting diode (LED) packages arranged in a matrix on the module substrate; and a controller configured to control the plurality of LED packages, wherein each of the plurality of LED packages includes: a package substrate; a pixel driving integrated circuit on the package substrate; and a first LED chip, a second LED chip, and a third LED chip on the pixel driving integrated circuit, wherein the pixel driving integrated circuit includes: a current regulator configured to generate first, second, and third reference currents having one of a first current level and a second current level; and an LED driver configured to generate, based on the first, second, and third reference currents, a first driving current, a second driving current, and a third driving current respectively applied to the first, second, and third LED chips and having a variable pulse width, and wherein the pixel driving integrated circuit is configured to control such that a unit emitting time of each of the first, second, and third LED chips is equal to or greater than 80% of a rise time of the first, second, and third LED chips.

### BRIEF DESCRIPTION OF THE DRAWINGS

Example embodiments will be more clearly understood from the following detailed description taken in conjunction with the accompanying drawings in which:

FIG. 1 is a schematic view illustrating a light emitting diode (LED) package according to example embodiments;

FIG. 2 is a circuit diagram of a pixel driving integrated circuit included in an LED package according to example embodiments;

FIG. 3A is a block diagram of a current regulator according to some example embodiments;

FIG. 3B is a circuit diagram of a control voltage generator and a voltage controlled current source, which are included in a current regulator, according to some example embodiments;

FIG. 4A is a block diagram of a current regulator according to some example embodiments;

FIG. 4B is a circuit diagram of a control voltage generator and a voltage controlled current source (VCCS), which are included in a current regulator, according to some example embodiments;

FIGS. 5A and 5B are graphs for describing an operation of a pixel driving integrated circuit, according to some example embodiments;

FIGS. 6A, 6B, 6C, 6D, 6E, and 6F are graphs for describing controlling of a driving current, according to some example embodiments;

FIGS. 7A, 7B, 7C, 7D, and 7E are circuit diagrams of pixel driving integrated circuits, according to some example embodiments;

FIG. 8A is a view illustrating an LED package according to some example embodiments, and FIG. 8B is a top view of the LED package of FIG. 8A;

FIG. 9A is a view illustrating an LED package according to some example embodiments, and FIG. 9B is a top view of the LED package of FIG. 9A;

FIG. 10 is a view illustrating of a display apparatus according to some example embodiments;

FIG. 11 is an enlarged plan view of region Ain FIG. 10;

FIG. 12 is a cross-sectional view of the display apparatus of FIG. 10;

FIG. 13 is a circuit diagram of a display apparatus according to some example embodiments;

FIG. 14 is a circuit diagram of a display apparatus according to some example embodiments;

FIG. 15A is a plan view of an LED package according to some example embodiments;

FIG. 15B is a plan view of a pixel driving integrated circuit according to some example embodiments;

FIG. 15C is a circuit diagram of a pixel driving integrated circuit according to some example embodiments; and

FIGS. 16 and 17 are plan views of LED packages according to some example embodiments.

### DETAILED DESCRIPTION

Hereinafter, certain embodiments according to the disclosure will be described in detail with reference to the accompanying drawings.

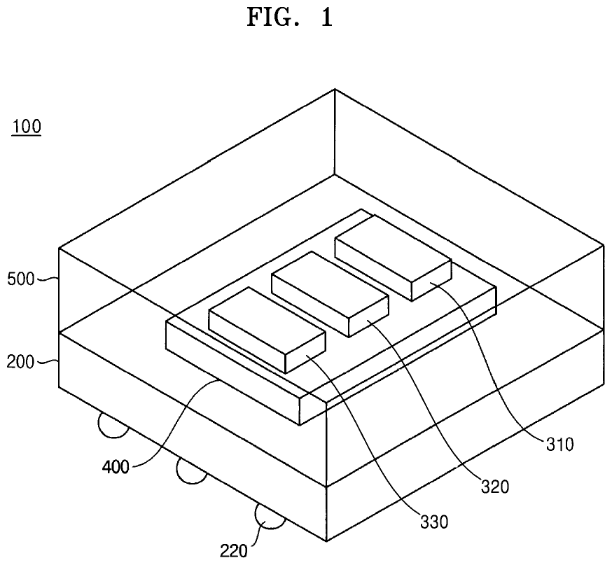

FIG. 1 is a schematic view illustrating a light emitting diode (LED) package 100 according to example embodiments.

Referring to FIG. 1, the LED package 100 includes a first LED chip 310, a second LED chip 320, and a third LED chip 330 and a pixel driving integrated circuit 400. The LED package 100 may further include a package substrate 200, an external connection terminal 220 such as solder or a bump, and a sealing member 500. While it is shown in FIG. 1 that the LED package 100 includes three LED chips, the disclosure is not limited thereto. According to some embodiments, an LED package may include at least four LED chips.

According to some example embodiments, the first, second, and third LED chips 310, 320, and 330 may emit different colors of light. For example, the first LED chip 310 may emit red light, the second LED chip 320 may emit green light, and the third LED chip 330 may emit blue light. In this case, the LED package 100 may be a red, green, blue (RGB) full color package.

According to some example embodiments, the first through the third LED chips 310, 320, and 330 may emit the same colors of light. For example, each of the first, second, and third LED chips 310, 320, and 330 may be a white LED chip configured to emit white light. In this case, the LED package 100 may be a multi-white package for vivid color.

According to some example embodiments, the color of light emitted by the first, second, and third LED chips 310, 320, and 330 may include at least one of various colors such as cyan, yellow, and magenta.

The first, second, and third LED chips 310, 320, and 330 may be arranged on a top surface of the pixel driving integrated circuit 400, and accordingly, light emitted from the first, second, and third LED chips 310, 320, and 330 may not be shaded by the pixel driving integrated circuit 400.

The pixel driving integrated circuit 400 may be arranged on or below the first, second, and third LED chips 310, 320, and 330 and may drive the first, second, and third LED chips 310, 320, and 330 using an active matrix. Here, the active matrix is a type of an addressing scheme used in flat panel displays. In a display apparatus using the active matrix, a pixel includes a storage element (e.g., a capacitor) for driving the pixel and a transistor programmable according to a signal. Pixels on one scan line may be programmed for about a period of {(frame time)÷(the number of scan lines)} based on an external signal. The voltage of each of the pixels is maintained due to a capacitor thereof, and accordingly, each pixel may continuously emit light during the remaining time of a frame. When a moving image is displayed on a display, a motion is segmented at regular intervals and continuously displayed. A time period corresponding to one frame is referred to as a frame time.

The pixel driving integrated circuit 400 may drive the first, second, and third LED chips 310, 320, and 330 using multi-mode pulse width modulation (PWM). The pixel driving integrated circuit 400 may control on-duty time of driving current of the first, second, and third LED chips 310, 320, and 330 in a single frame period to control the luminance of the first, second, and third LED chips 310, 320, and 330.

For example, the pixel driving integrated circuit 400 may increase the pulse width (i.e., the duty ratio) of a current for driving the first, second, and third LED chips 310, 320, and 330 when the first, second, and third LED chips 310, 320, and 330 display high gray-scale (i.e., high luminance) and decrease the pulse width of the current when the first, second, and third LED chips 310, 320, and 330 display low gray-scale (i.e., low luminance). On the other hand, pulse amplitude modulation (PAM) controls an amplitude of a current pulse. Unlike PAM, PWM may prevent a current from being lower than a level necessary for the reliable operation of the first, second, and third LED chips 310, 320, and 330 at low gray-scale.

According to some embodiments, the pixel driving integrated circuit 400 may drive the first, second, and third LED chips 310, 320, and 330 in another mode using PWM, depending on gray scale (or luminance). For example, frame data received by the pixel driving integrated circuit 400 may include a signal for selecting a mode of the pixel driving integrated circuit 400.

The signal for selecting a mode may include a single bit. In this case, when the gray scale is equal to or greater than a threshold, the single bit may be ‘1’, and the pixel driving integrated circuit 400 may drive the first, second, and third LED chips 310, 320, and 330 in a first mode, in which PWM is performed at a first current level. When the gray scale is lower than the threshold, the single bit may be ‘0’, and the pixel driving integrated circuit 400 may drive the first, second, and third LED chips 310, 320, and 330 in a second mode, in which PWM is performed at a second current level that is lower than the first current level.

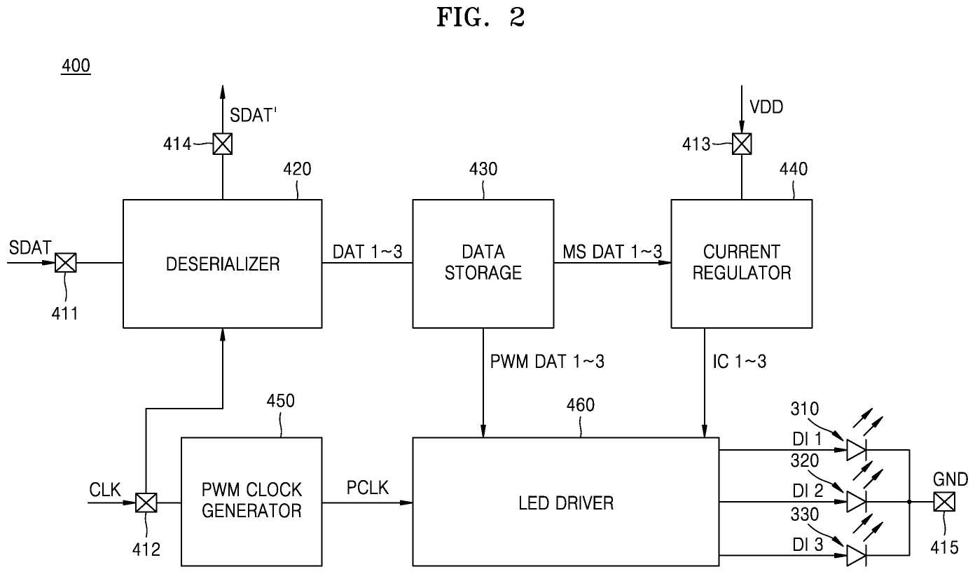

The first and second current levels indicate the magnitude of a non-zero current. In other words, first, second, and third driving currents DI 1, DI 2, and DI 3 (in FIG. 2) supplied by the pixel driving integrated circuit 400 to the first, second, and third LED chips 310, 320, and 330 may have at least three levels including 0[A].

According to some embodiments, the signal for selecting a mode may include at least two bits. Accordingly, the pixel driving integrated circuit 400 may drive the first, second, and third LED chips 310, 320, and 330 in at least four modes using PWM. For example, when the signal for selecting a mode includes two bits, a driving current of the pixel driving integrated circuit 400 may operate in four different modes using PWM. When the signal for selecting a mode includes three bits, a driving current of the pixel driving integrated circuit 400 may operate in eight different modes using PWM.

The pixel driving integrated circuit 400 may be arranged on the package substrate 200. In the embodiments of FIG. 1, various wiring structures including a through silicon via (TSV) may be formed in the pixel driving integrated circuit 400. The pixel driving integrated circuit 400 may be configured to be electrically connected to the package substrate 200 through an external connection terminal such as solder or a bump. The pixel driving integrated circuit 400 may include a plurality of pads for connection between the package substrate 200 and the pixel driving integrated circuit 400. The pads may be formed on a bottom surface of the pixel driving integrated circuit 400 and are not shown in FIG. 1. The pads may include a data input pad 411 (in FIG. 2), a clock pad 412 (in FIG. 2), a power pad 413 (in FIG. 2), a data output pad 414 (in FIG. 2), a ground pad 415 (in FIG. 2), and an auxiliary power pad.

In the embodiments of FIG. 1, the first, second, and third LED chips 310, 320, and 330 may be implemented as flip chips. In detail, the first, second, and third LED chips 310, 320, and 330 may be connected to the pixel driving integrated circuit 400 through at least one electrode. In addition, the pixel driving integrated circuit 400 on or below the first, second, and third LED chips 310, 320, and 330 may include at least one pad for electrical connection to the first, second, and third LED chips 310, 320, and 330. The first, second, and third LED chips 310, 320, and 330 may be electrically connected to the pixel driving integrated circuit 400 through a conductive adhesive material such as eutectic metal, paste, or solder.

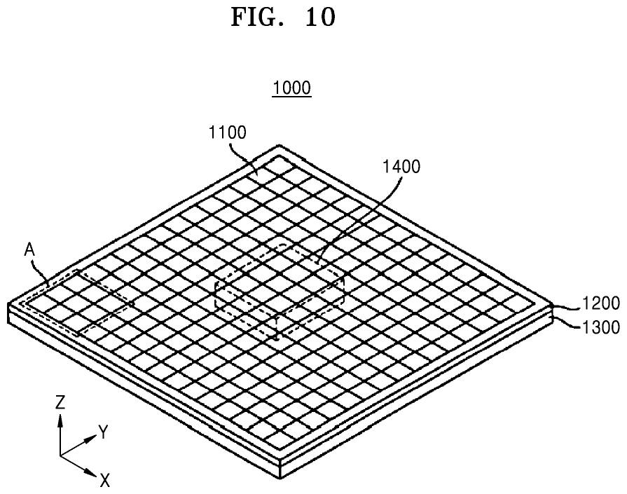

The package substrate 200 may be arranged on or below the pixel driving integrated circuit 400. The first, second, and third LED chips 310, 320, and 330 of an LED pixel and the pixel driving integrated circuit 400 may be mounted on the package substrate 200 and may communicate with an external controller (1400 in FIG. 10) through the package substrate 200 and an external printed circuit board (PCB) (1300 in FIG. 10).

The package substrate 200 may include a plurality of pads for electrical connection to the pixel driving integrated circuit 400. The pads of the package substrate 200 may include a data input pad, a clock pad, a power pad, a data output pad, a ground pad, and an auxiliary power pad and may be arranged between the package substrate 200 and the pixel driving integrated circuit 400 so as not to be exposed. An adhesive member, such as epoxy, silicone, acrylate, and/or paste, may be between the pixel driving integrated circuit 400 and the package substrate 200 to fix the pixel driving integrated circuit 400 and the package substrate 200 to each other.

The first, second, and third LED chips 310, 320, and 330 of the LED pixel and the pixel driving integrated circuit 400 may be fixed to the package substrate 200 by the sealing member 500 that is transparent. The sealing member 500 may include an epoxy resin, a silicone resin, or the like. The sealing member 500 may further include a filler such as fused silica or carbon black.

According to some embodiments, the LED package 100 of FIG. 1 may be provided by preparing the package substrate 200; attaching the pixel driving integrated circuit 400 to the package substrate 200 using a conductive adhesive material and an adhesive member; bonding the first, second, and third LED chips 310, 320, and 330 to the pixel driving integrated circuit 400 using a conductive adhesive material; molding a package using the sealing member 500; and sawing or singulating the molded package.

FIG. 2 is a circuit diagram of the pixel driving integrated circuit 400 included in the LED package 100.

Referring to FIG. 2, the pixel driving integrated circuit 400 includes a plurality of pads, e.g., the data input pad 411, the clock pad 412, the power pad 413, the data output pad 414, and the ground pad 415, a deserializer 420, a data storage 430, a current regulator 440, a PWM clock generator 450, and an LED driver 460.

The deserializer 420 may receive serial data SDAT through the data input pad 411 from the controller 1400 (in FIG. 10) outside the pixel driving integrated circuit 400, extract frame data for the first, second, and third LED chips 310, 320, and 330 from the serial data SDAT, and output first, second, and third driving data DAT 1, DAT 2, and DAT 3 based on the frame data.

According to some embodiments, the frame data may include first PWM data PWM DAT 1, second PWM data PWM DAT 2, and third PWM data PWM DAT 3 for controlling the LED driver 460 and first mode select data MS DAT 1, second mode select data MS DAT 2, and third mode select data MS DAT 3 for selecting an operating mode. According to some embodiments, the first, second, and third mode select data MS DAT 1˜3 may include a single bit. According to some embodiments, the first, second, and third mode select data MS DAT 1˜3 may include at least two bits. For example, the frame data may include gray-scale data of an image signal and may further include additional gray-scale data to respond to unintended low efficiency and wavelength shift of a pixel.

The deserializer 420 may output, without processing, remaining serial data SDAT′ of the serial data SDAT except for the frame data corresponding to the pixel driving integrated circuit 400. The remaining serial data SDAT′ may be output through the data output pad 414 and provided to a subsequent LED package (e.g., an LED package of a subsequent scan line). Because a plurality of LED packages are connected in series to each other in a display apparatus 1000 (in FIG. 10), the serial data SDAT for a single frame period may include frame data of the plurality of LED packages.

For example, an LED package of a first scan line may acquire frame data only for itself and output remaining data to an LED package of a second scan line, and the LED package of the second scan line may also acquire frame data only for itself and output remaining data to an LED package of a third scan line. In this way, each of the respective LED packages of the first to last scan lines may acquire frame data for itself.

The data storage 430 may store the first, second, and third driving data DAT 1˜3 for respectively driving the first, second, and third LED chips 310, 320, and 330. In an embodiment, the data storage 430 may be implemented as a latch, a register, a buffer, or the like and may include at least one selected from volatile memory, such as static random access memory (SRAM) and dynamic RAM (DRAM), and/or non-volatile memory, such as electrically erasable programmable read-only memory (EEPROM), flash memory, phase-change RAM (PRAM), resistance RAM (RRAM), nano floating gate memory (NFGM), polymer RAM (PoRAM), magnetic RAM (MRAM), and ferroelectric RAM (FRAM).

The current regulator 440 may receive a power supply voltage VDD through the power pad 413 and generate a first reference current IC 1, a second reference current IC 2, and a third reference current IC 3 based on the power supply voltage VDD and the first, second, and third mode select data MS DAT 1˜3. According to some embodiments, the current regulator 440 may include a current mirror.

The PWM clock generator 450 may generate a PWM clock signal PCLK based on a clock signal CLK received through the clock pad 412. A frequency of the PWM clock signal PCLK may be less than a frequency of the clock signal CLK but is not limited thereto. A period of the PWM clock signal PCLK may be greater than a period of the clock signal CLK but is not limited thereto.

According to some embodiments, a unit emitting time of the first, second, and third LED chips 310, 320, and 330 may be at least 80% of a rise time of the first, second, and third LED chips 310, 320, and 330. According to some embodiments, the unit emitting time of the first, second, and third LED chips 310, 320, and 330 may be greater than the rise time of the first, second, and third LED chips 310, 320, and 330. According to some embodiments, the unit emitting time may be at least about 200 ns. According to some embodiments, the unit emitting time may be at least about 300 ns. According to some embodiments, the unit emitting time may be at least about 500 ns. Here, the unit emitting time represents the shortest ‘on’ time period in which the first, second, and third LED chips 310, 320, and 330 have the lowest luminance. The rise time is a time taken for an output (e.g., the amplitude of a driving current or luminance) of the first, second, and third LED chips 310, 320, and 330 to increase from 10% of a target value to 90% of the target value.

According to some embodiments, the unit emitting time of the first, second, and third LED chips 310, 320, and 330 may be equal to or greater than the period of the PWM clock signal PCLK. According to some embodiments, the unit emitting time of the first, second, and third LED chips 310, 320, and 330 may be N times the period of the PWM clock signal PCLK, where N is an integer of at least 2.

The LED driver 460 may generate the first, second, and third driving currents DI 1, DI 2, and DI 3, which are respectively applied to the first, second, and third LED chips 310, 320, and 330, based on the PWM clock signal PCLK, the distributed frame data (e.g., the first, second, and third PWM data PWM DAT 1˜3) provided from the data storage 430, and the first, second, and third reference currents IC 1˜3 provided from the current regulator 440.

The first, second, and third driving currents DI 1, DI 2, and DI 3 may be generated based on PWM. For example, the first, second, and third driving currents DI 1, DI 2, and DI 3 may have current levels respectively determined based on the first, second, and third mode select data MS DAT 1˜3 and have pulse widths (e.g., on-duty times) respectively determined based on the first, second, and third PWM data PWM DAT 1˜3.

Each of the first, second, and third LED chips 310, 320, and 330 may include an anode, which receives a corresponding one of the first, second, and third driving currents DI 1, DI 2, and DI 3 from the LED driver 460, and a cathode, which is connected to the ground pad 415 providing a ground potential GND.

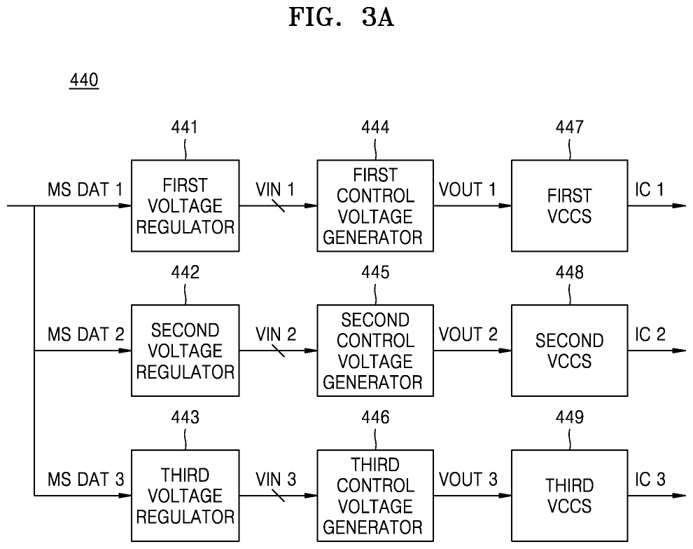

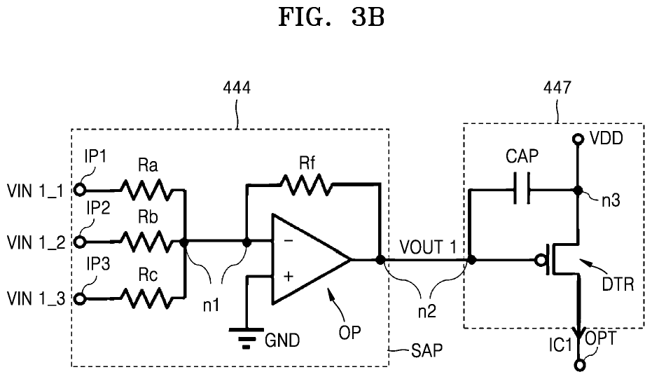

FIG. 3A is a block diagram of the current regulator 440 according to some embodiments. FIG. 3B is a circuit diagram of a first control voltage generator 444 and a first voltage controlled current source (VCCS) 447, which are included in the current regulator 440, according to some embodiments.

Referring to FIG. 3A, the current regulator 440 may include a first voltage regulator 441, a second voltage regulator 442, and a third voltage regulator 443, the first control voltage generator 444, a second control voltage generator 445, and a third control voltage generator 446, the first VCCS 447, a second VCCS 448, and a third VCCS 449.

The first, second, and third voltage regulators 441, 442, and 443 may respectively generate first, second, and third input voltages VIN 1, VIN 2, and VIN 3 based on, respectively, the first, second, and third mode select data MS DAT 1˜3, which are digital signals. The first, second, and third input voltages VIN 1, VIN 2, and VIN 3 may have a reference potential or a set voltage (e.g., 1[V]) according to the first, second, and third mode select data MS DAT 1˜3, respectively.

Each of the first, second, and third input voltages VIN 1, VIN 2, and VIN 3 may include a plurality of voltages, which are respectively output to different terminals, based on the number of bits in each of the first, second, and third mode select data MS DAT 1˜3. In detail, when the number of bits in each of the first, second, and third mode select data MS DAT 1˜3 is ‘n’, each of the first, second, and third input voltages VIN 1, VIN 2, and VIN 3 may include ‘n’ voltage values respectively output to different terminals. For example, the first, second, and third voltage regulators 441, 442, and 443 may respectively include serial-to-parallel converters configured to generate the first, second, and third input voltages VIN 1, VIN 2, and VIN 3 based on the first, second, and third mode select data MS DAT 1˜3, respectively, wherein each of the first, second, and third mode select data MS DAT 1˜3 is a serial digital bit stream and each of the first, second, and third input voltages VIN 1, VIN 2, and VIN 3 includes a plurality of parallel voltages.

According to some embodiments, each of the first, second, and third voltage regulators 441, 442, and 443 may further include a step-up circuit configured to generate a corresponding one of the first, second, and third input voltages VIN 1, VIN 2, and VIN 3 based on a corresponding one of the first, second, and third mode select data MS DAT 1˜3 (in FIG. 2). The step-up circuit may include, for example a boost converter.

The first, second, and third control voltage generators 444, 445, and 446 may generate first, second, and third output voltages VOUT 1, VOUT 2, and VOUT 3 based on the first, second, and third input voltages VIN 1, VIN 2, and VIN 3, respectively. According to some embodiments, each of the first, second, and third control voltage generators 444, 445, and 446 may include an amplifier circuit, which generates one output voltage based on at least one input voltage.

The first, second, and third VCCSs 447, 448, and 449 may output the first, second, and third reference currents IC 1, IC 2, and IC 3 based on the first, second, and third output voltages VOUT 1, VOUT 2, and VOUT 3, respectively. Each of the first, second, and third VCCSs 447, 448, and 449 may include a voltage maintaining element (e.g., a capacitor) configured to maintain, to be constant, a corresponding one of the first, second, and third output voltages VOUT 1, VOUT 2, and VOUT 3, which are applied during a frame period. Each of the first, second, and third output voltages VOUT 1, VOUT 2, and VOUT 3 may further include a driving element (e.g., a transistor), which controls the magnitude of a corresponding one of the first, second, and third reference currents IC 1, IC 2, and IC 3 based on a corresponding one of the first, second, and third output voltages VOUT 1, VOUT 2, and VOUT 3.

Referring to FIG. 3B, the first control voltage generator 444 may be a summing amplifier, and the first VCCS 447 may include a capacitor CAP and a driving transistor DTR. Each of the second and the third control voltage generators 445 and 446 may be substantially the same as the first control voltage generator 444, and each of the second and the third VCCSs 448 and 449 may be substantially the same as the first VCCS 447.

The first control voltage generator 444 may include a first input terminal IP1, a second input terminal IP2, and a third input terminal IP3, to which the first through the third input voltages VIN 1_1, VIN 1_2, and VIN 1_3 are respectively applied, an operational amplifier OP, a first input resistor Ra, a second input resistor Rb, and a third input resistor Rc, and a feedback resistor Rf.

When the first mode select data MS DAT 1 is expressed in three bits, the first input voltages VIN 1_1, VIN 1_2, and VIN 1_3 are voltage values respectively corresponding to the three bits. Hereinafter, an example in which the first input voltages VIN 1_1, VIN 1_2, and VIN 1_3 have a value of 0[V] or 1[V] is described, but this is only for convenience of description and does not limit the inventive concept in any way. The first input voltages VIN 1_1, VIN 1_2, and VIN 1_3 may have a voltage value of 0[V] and a random non-zero voltage value (e.g., 5[V]).

The first, second, and third input resistors Ra, Rb, and Rc may be respectively connected between the first, second, and third input terminals IP1, IP2, and IP3 and a first node n1. A reference potential may be applied to a non-inverting input terminal of the operational amplifier OP, and an inverting input terminal of the operational amplifier OP may be connected to the first node n1. The feedback resistor Rf may be connected between the inverting input terminal and an output terminal of the operational amplifier OP.

The output terminal of the operational amplifier OP, a first terminal of the capacitor CAP, and a gate electrode of the driving transistor DTR may be connected in common to one node, which is referred to as a second node n2. A second terminal of the capacitor CAP and a source electrode of the driving transistor DTR may be connected to a third node n3, to which the power supply voltage VDD is applied. The first reference current IC 1 may have a different magnitude according to a voltage applied to the gate electrode of the driving transistor DTR. The first reference current IC 1 may be output to an output terminal OPT through a drain electrode of the driving transistor DTR.

For example, the first, second, and third input resistors Ra, Rb, and Rc and the feedback resistor Rf may satisfy Formula 1.

$$Ra = \frac{R b}{2} = \frac{R c}{4} = R f \qquad [ Formula 1 ]$$

In this case, an output of the operational amplifier OP is expressed as Formula 2.

$$Vo = - \frac{VIN1\_ 1}{2} - \frac{VIN1\_ 2}{4} - \frac{VIN1\_ 3}{8} \qquad [ Formula 2 ]$$

Table 1 shows the first output voltage VOUT 1 of the operational amplifier OP according to the first input voltages VIN 1_1, VIN 1_2, and VIN 1_3.

TABLE 1

| VIN 1_1[V] | VIN 1_2[V] | VIN 1_3[V] | VOUT 1[V] |
|---|---|---|---|
| 0 | 0 | 0 | 0 |
| 0 | 0 | 1 | −⅛ |
| 0 | 1 | 0 | − 2/8 |
| 0 | 1 | 1 | −⅜ |
| 1 | 0 | 0 | − 4/8 |
| 1 | 0 | 1 | −⅝ |
| 1 | 1 | 0 | − 6/8 |
| 1 | 1 | 1 | −⅞ |

In the case of FIG. 3B, the first reference current IC 1 may have eight different magnitudes according to eight values of the first output voltage VOUT 1. In other words, the output current the first reference current IC 1 may be a constant current having one of eight different magnitudes. According to some embodiments, the output current the first reference current IC 1 may be proportional to the magnitude of the first output voltage VOUT 1. According to the embodiment of FIG. 3B, the LED package 100 (in FIG. 1) may operate in first through eighth modes respectively using eight different levels of current. In this case, the first through eighth modes operate using PWM at first through eighth current levels, respectively, which sequentially decrease, and respectively correspond to different gray scales in decreasing order.

Although it is described that the first control voltage generator 444 and the first VCCS 447 are driven based on 3-bit mode select data in FIG. 3B, one of skill in the art should understand that a control voltage generator and a VCCS may be driven based on 1-bit, 2-bit, or at least 4-bit mode select data.

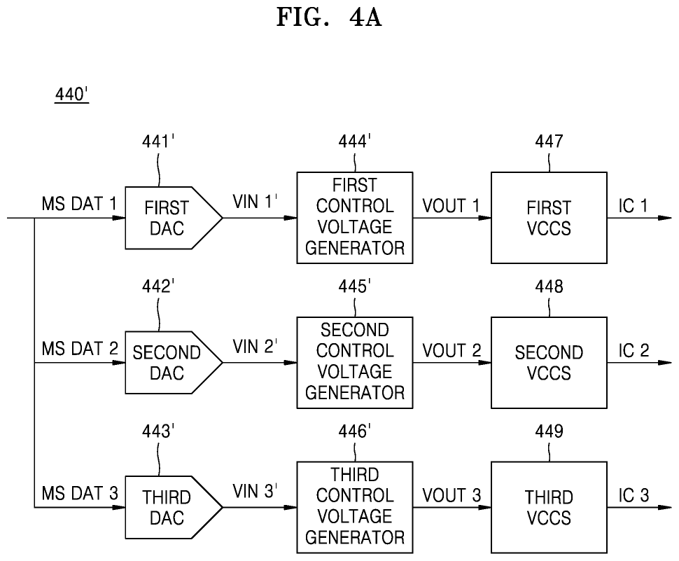

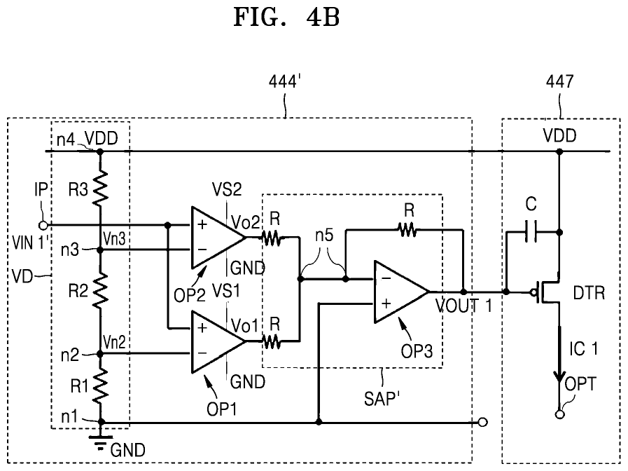

FIG. 4A is a block diagram of a current regulator 440′ according to some embodiments. FIG. 4B is a circuit diagram of a first control voltage generator 444′ and the first VCCS 447, which are included in the current regulator 440′, according to some embodiments.

Referring to FIG. 4A, the current regulator 440′ may include a first digital-to-analog converter (DAC) 441′, a second DAC 442′, and a third DAC 443′, a first control voltage generator 444′, a second control voltage generator 445′, and a third control voltage generator 446′, and the first through the third VCCSs 447, 448, and 449.

The first, second, and third DACs 441′, 442′, and 443′ may generate first, second, and third input voltages VIN 1′, VIN 2′, and VIN 3′, which are analog voltages, based on the first, second, and third mode select data MS DAT 1˜3, respectively, which are digital signals. Each of the first, second, and third input voltages VIN 1′, VIN 2′, and VIN 3′ may have a single voltage level unlike the first, second, and third input voltages VIN 1, VIN 2, and VIN 3 in FIG. 3A.

The first, second, and third control voltage generators 444′, 445′, and 446′ may generate first, second, and third output voltages VOUT 1, VOUT 2, and VOUT 3 based on the first, second, and third input voltages VIN 1′, VIN 2′, and VIN 3′, respectively. According to some embodiments, each of the first, second, and third control voltage generators 444′, 445′, and 446′ may include a voltage controlled voltage source, which generates one output voltage based on one input voltage.

The first, second, and third VCCSs 447, 448, and 449 are substantially the same as those described with reference to FIGS. 3A and 3B, and thus detailed descriptions thereof will be omitted.

Referring to FIG. 4B, the first control voltage generator 444′ may include an input terminal IP, a voltage divider VD, a first operational amplifier OP1 and a second operational amplifier OP2, and a summing amplifier SAP′.

The voltage divider VD may include a first resistor R1, a second resistor R2, and a third resistor R3 connected in series between a first node n1 and a fourth node n4. The ground potential GND may be applied to the first node n1, and the power supply voltage VDD may be applied to the fourth node n4. A first terminal of the first resistor R1 may be connected to the first node n1, and a second terminal of the first resistor R1 may be connected to a first terminal of the second resistor R2 at the second node n2. A second terminal of the second resistor R2 may be connected to a first terminal of the third resistor R3 at a third node n3. A second terminal of the third resistor R3 may be connected to the fourth node n4.

The first and the second operational amplifiers OP1 and OP2 may be comparators. A first output voltage Vo1 of the first operational amplifier OP1 may be equal to a first supply voltage VS1 when the first input voltage VIN 1′ of the input terminal IP is greater than a second node voltage Vn2 of the second node n2 and may be equal to the ground potential GND when the first input voltage VIN 1′ of the input terminal IP is less than the second node voltage Vn2 of the second node n2. A second output voltage Vo2 of the second operational amplifier OP2 may be equal to a second supply voltage VS2 when the first input voltage VIN 1′ of the input terminal IP is greater than a third node voltage Vn3 of the third node n3 and may be equal to the ground potential GND when the first input voltage VIN 1′ of the input terminal IP is less than the third node voltage Vn3 of the third node n3.

The second and the third node voltages Vn2 and Vn3 may be expressed as Formula 3.

$$Vn 2 = \frac{R 1}{R 1 + R 2 + R 3} VDD , \\ Vn 3 = \frac{R 1 + R 2}{R 1 + R 2 + R 3} VDD \qquad [ Formula 3 ]$$

The first output voltage VOUT 1 of the summing amplifier SAP′, which includes resistors R and a third operational amplifier OP3, may be expressed as Formula 4.

[Formula 4]

VOUT1=−Vo1−Vo2

Table 2 shows output values of the first, second, and third operational amplifiers OP1, OP2, and OP3 according to the ranges of the first input voltage VIN.

TABLE 2

| | | | VOUT |
|---|---|---|---|
| VIN 1′ | Vo1 | Vo2 | 1 |
| $VIN {1}^{′} < \frac{R 1}{R 1 + R 2 + R 3} VDD$ | 0 | 0 | 0 |
| $\frac{R 1}{R 1 + R 2 + R 3} VDD \leq VIN {1}^{′} < \frac{R 1 + R 2}{R 1 + R 2 + R 3} VDD$ | VS1 | 0 | −VS1 |
| $\frac{R 1 + R 2}{R 1 + R 2 + R 3} VDD \leq VIN {1}^{′}$ | VS1 | VS2 | −VS1- VS2 |

In the embodiment of FIG. 4B, the first output voltage VOUT 1 may have one of three voltage levels, and accordingly, the current regulator 440′ may output the first reference current IC 1 at one of three non-zero levels to an output terminal OPT. According to the embodiment of FIG. 4B, the LED package 100 (in FIG. 1) may operate in any one of first, second, and third modes based on a corresponding one of three different levels of current.

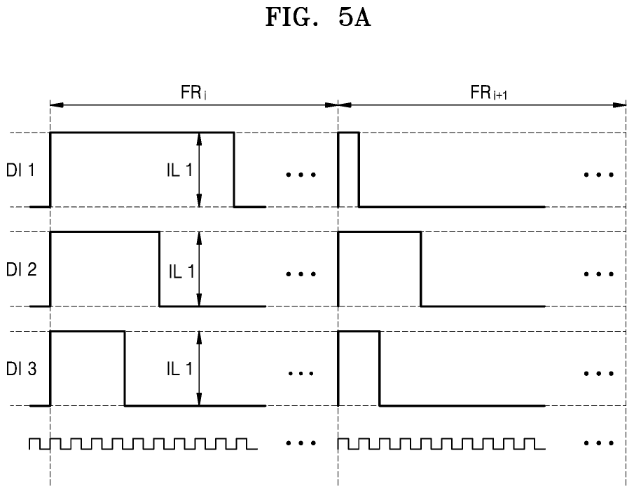

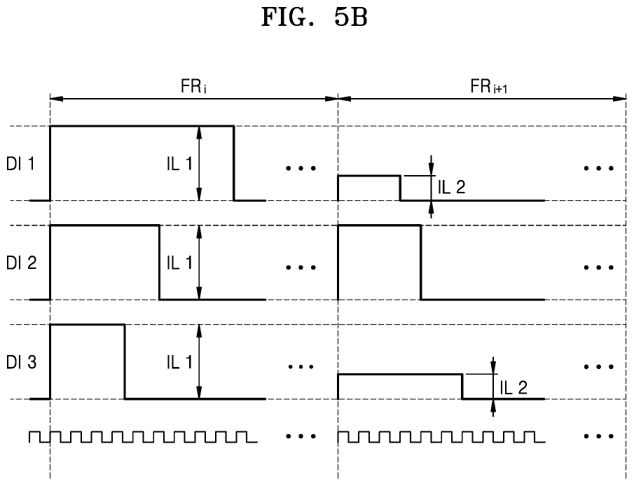

FIGS. 5A and 5B are graphs for describing the operation of the pixel driving integrated circuit 400 (in FIG. 2), according to some embodiments. In detail, FIG. 5A is a graph showing the first, second, and third driving currents DI 1, DI 2, and DI 3 during PWM using a single current level in a comparative example; and FIG. 5B is a graph showing the first, second, and third driving currents DI 1, DI 2, and DI 3 during multi-mode PWM, according to some embodiments.

FIGS. 5A and 5B show changes in the first, second, and third driving currents DI 1, DI 2, and DI 3 for displaying the same image information in an i-th frame FRᵢ and an (i+1)-th frame FRᵢ₊₁ following the i-th frame FRᵢ.

Referring to FIG. 5A, the PWM method according to the related art represents gray scale by changing a pulse width at a single current level, i.e., a first current level IL 1. Accordingly, when gray-scale resolution increases, the unit emitting time of the first, second, and third LED chips 310, 320, and 330 (in FIG. 1) becomes too short compared to the rise time of the LED chips 310, 320, and 330 under PWM control.

For example, when data about gray scale includes 16 bits (that is, when gray-scale resolution is 2¹⁶), the unit emitting time corresponding to a minimum emitting time of an LED is {(a frame time)÷2¹⁶} [sec]. Assuming that the number of lines controlled by a single controller is 32 and a refresh rate is 90 Hz in a display apparatus using an LED, the frame time is about 0.347 ms and the unit emitting time is about 5.3 ns.

On the other hand, the rise time of LED chips is typically several hundreds of ns, and therefore, when high gray-scale resolution is used, the unit emitting time is too short, compared to the rise time of the LED chips, under the PWM control according to the related art. Accordingly, the reliability in flickering of LED chips and the reliability in operating an LED package may decrease.

Referring to FIG. 5B, according to example embodiments, the pixel driving integrated circuit 400 uses an active matrix control method and a PWM control method based on a plurality of current levels, e.g., the first current level IL 1 and a second current level IL 2, when driving a pixel. When the active matrix is used, the unit emitting time increases in proportion to the number of lines controlled by the controller (e.g., 32 times in case the number of lines is 32).

The brightness of an LED in a single frame is proportional to a magnitude of an area of a graph representing a current of an LED over time. Accordingly, when a low gray level is represented, the pulse width of a driving current may be modulated based on a low level of current, and accordingly, the unit emitting time may be increased. Referring to FIG. 5B, the second current level IL 2 is about ⅓ of the first current level IL 1. When the first driving current DI 1 in the (i+1)-th frame FRi+1 is compared between FIGS. 5A and 5B, the pulse width in FIG. 5A is about half of the period of the PWM clock signal PCLK while the pulse width in FIG. 5B is about 3/2 of the period of the PWM clock signal PCLK. In other words, according to example embodiments, the unit emitting time of the LED package 100 (in FIG. 1) is about 508 ns, which is 96 times greater than the unit emitting time of about 5.3 ns in the case where a passive matrix using a single level of current is used in the related art, and is sufficiently long compared to the rise time of the first, second, and third LED chips 310, 320, and 330 (in FIG. 1). Therefore, the LED package 100 (in FIG. 1) may reliably operate.

According to some embodiments, when gray-scale resolution is 2ⁿ, the unit emitting time of the first, second, and third LED chips 310, 320, and 330 (in FIG. 1) may be expressed as Formulae 5 and 6.

$$\begin{matrix}\frac{( frame time )}{{2}^{n}} < ( unit emitting time ) & [ Formula 5 ] \\ N \times \frac{( frame time )}{{2}^{n}} = ( unit emitting time ) & [ Formula 6 ]\end{matrix}$$

In Formula 6, N is an integer of at least 2, which is determined according to current levels of the first, second, and third reference currents IC 1, IC 2, and IC 3 of the current regulator 440 (in FIG. 2).

According to example embodiments, even when the LED package 100 (in FIG. 1) uses high gray-scale resolution and outputs low-luminance light, the unit emitting time is sufficiently long, and therefore, the reliability of operation of the LED package 100 (in FIG. 1) may be enhanced.

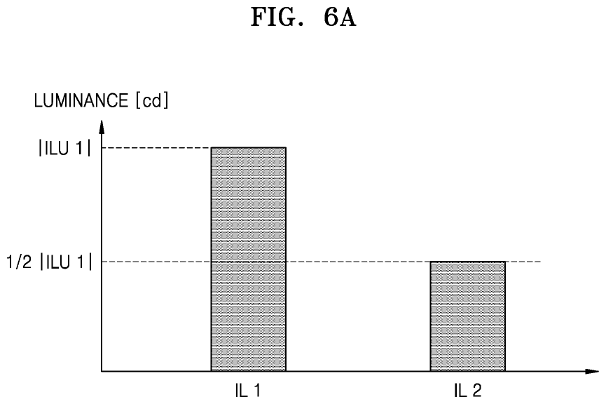

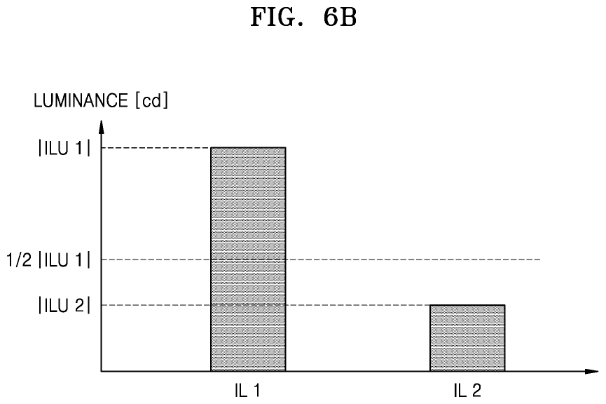

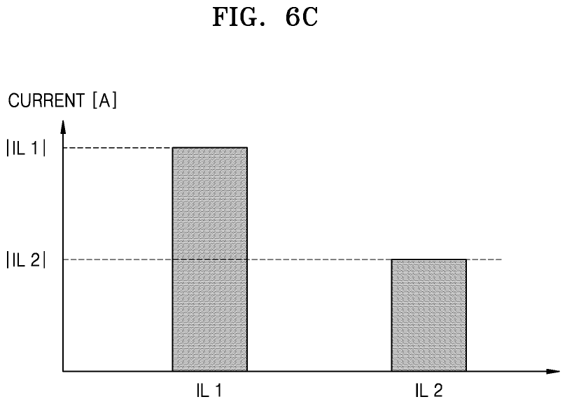

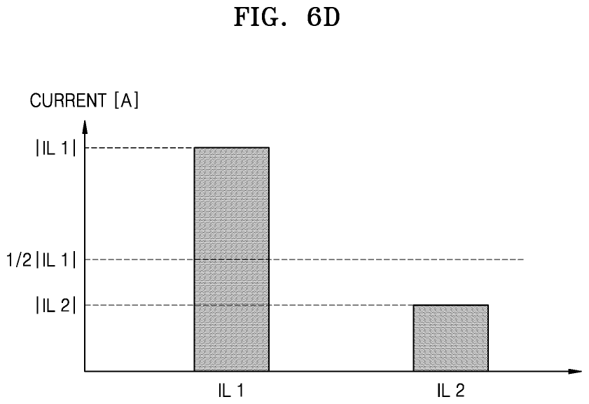

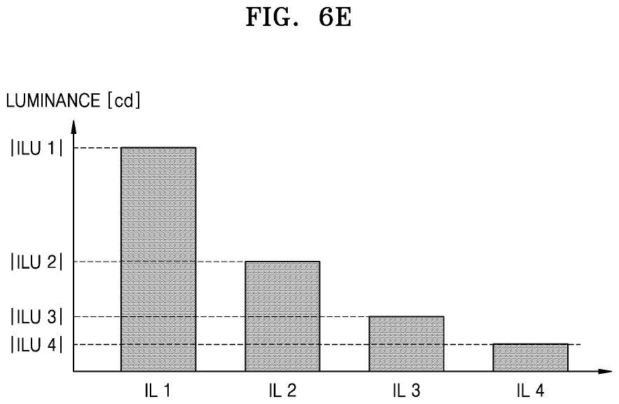

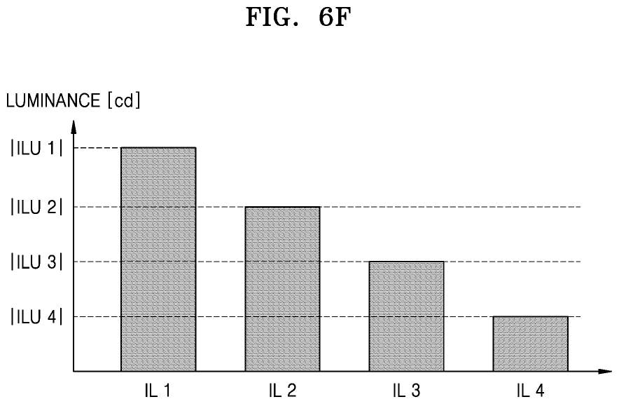

FIGS. 6A, 6B, 6C, 6D, and 6F are graphs for describing controlling of a driving current, according to some embodiments. FIGS. 6A through 6D illustrate example cases where the first, second, and third mode select data MS DAT 1˜3 (in FIG. 2) include one bit and the first, second, and third driving currents DI 1, DI 2, and DI 3 (in FIG. 2) have two current levels. FIGS. 6E and 6F illustrate example cases where the first, second, and third mode select data MS DAT 1˜3 (in FIG. 2) include two bits and the first, second, and third driving currents DI 1, DI 2, and DI 3 (in FIG. 2) have four current levels.

Referring to FIG. 6A, the magnitude of the first, second, and third driving currents DI 1, DI 2, and DI 3 (in FIG. 2) may have a value of the first current level IL1 or the second current level IL 2. According to some embodiments, luminance ILU 2 of the first, second, and third LED chips 310, 320, and 330 (in FIG. 1) when the first, second, and third LED chips 310, 320, and 330 (in FIG. 1) are driven at the second current level IL 2 may be half of luminance ILU 1 of the first, second, and third LED chips 310, 320, and 330 (in FIG. 1) when driven at the first current level IL 1.

Referring to FIG. 6B, the luminance ILU 2 of the first, second, and third LED chips 310, 320, and 330 (in FIG. 1) when the first, second, and third LED chips 310, 320, and 330 (in FIG. 1) are driven at the second current level IL 2 may be equal to or less than half of the luminance ILU 1 of the first, second, and third LED chips 310, 320, and 330 (in FIG. 1) when driven at the first current level IL 1. According to some embodiments, the luminance ILU 2 of the first, second, and third LED chips 310, 320, and 330 (in FIG. 1) when the first, second, and third LED chips 310, 320, and 330 (in FIG. 1) are driven at the second current level IL 2 may be about 30% to about 50% of the luminance ILU 1 of the first, second, and third LED chips 310, 320, and 330 (in FIG. 1) when driven at the first current level IL 1.

Referring to FIG. 6C, the second current level IL 2 may be about half of the first current level IL 1.

Referring to FIG. 6D, the second current level IL 2 may be equal to or less than about 50% of the first current level IL 1. According to some embodiments, the second current level IL 2 may be about 30% to about 40% of the first current level IL 1.

Referring to FIG. 6E, the magnitude of the first, second, and third driving currents DI 1, DI 2, and DI 3 (in FIG. 2) may have a value of one of first through fourth current levels IL 1, IL 2, IL 3, and IL 4. According to some embodiments, when each of the first, second, and third LED chips 310, 320, and 330 (in FIG. 1) is sequentially driven at the first through fourth current levels IL 1, IL 2, IL 3, and IL 4, each of the first, second, and third LED chips 310, 320, and 330 (in FIG. 1) may sequentially have first through fourth luminance ILU 1, ILU 2, ILU 3, and ILU 4. According to some embodiments, the second luminance ILU 2 may be about half of the first luminance ILU 1. According to some embodiments, the third luminance ILU 3 may be about half of the second luminance ILU 2. According to some embodiments, the fourth luminance ILU 4 may be about half of the third luminance ILU 3. According to some embodiments, when a current level corresponding to low gray scale is divided into a plurality of levels, gray scale may be more effectively represented.

Referring to FIG. 6F, according to some embodiments, the second luminance ILU 2 may be about ¾ of the first luminance ILU 1, and the third luminance ILU 3 may be about half of the first luminance ILU 1. According to some embodiments, the fourth luminance ILU 4 may be about ¼ of the first luminance ILU 1.

While various forms of controlling a driving current are shown in FIGS. 6A-6F, it should be understood that the disclosure is not limited to the above-described examples. The driving current of the LED chip may have various numbers and magnitudes of current levels to effectively represent different gray scales.

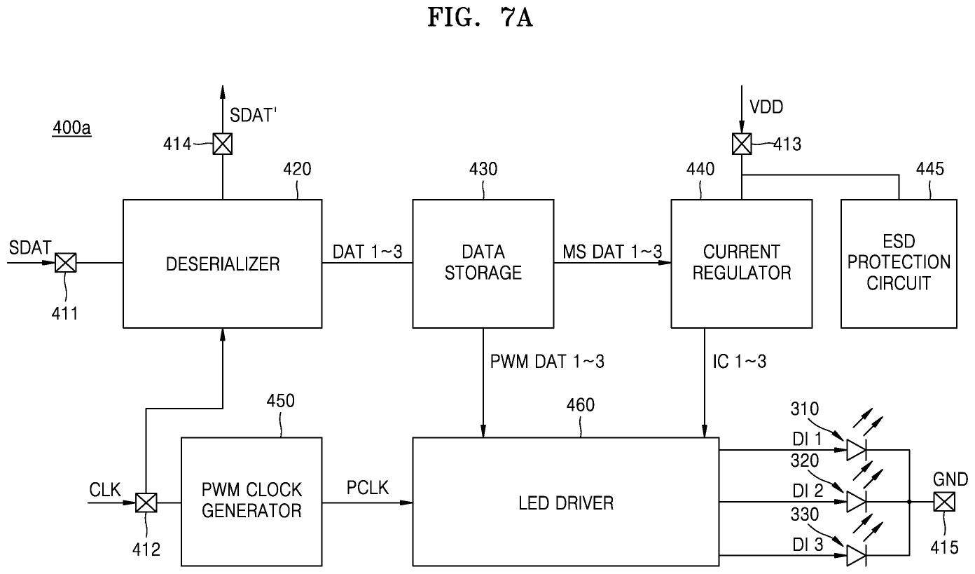

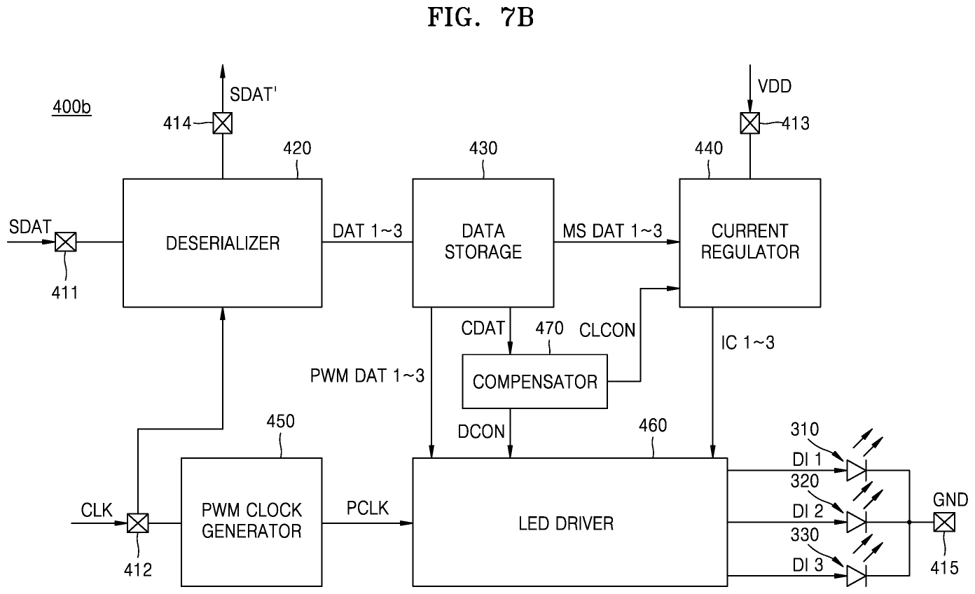

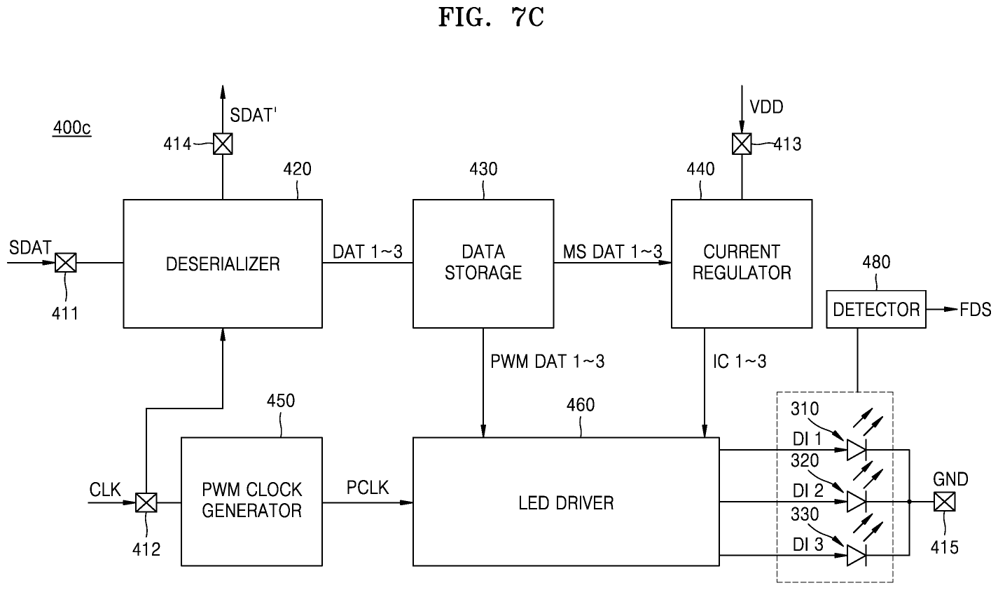

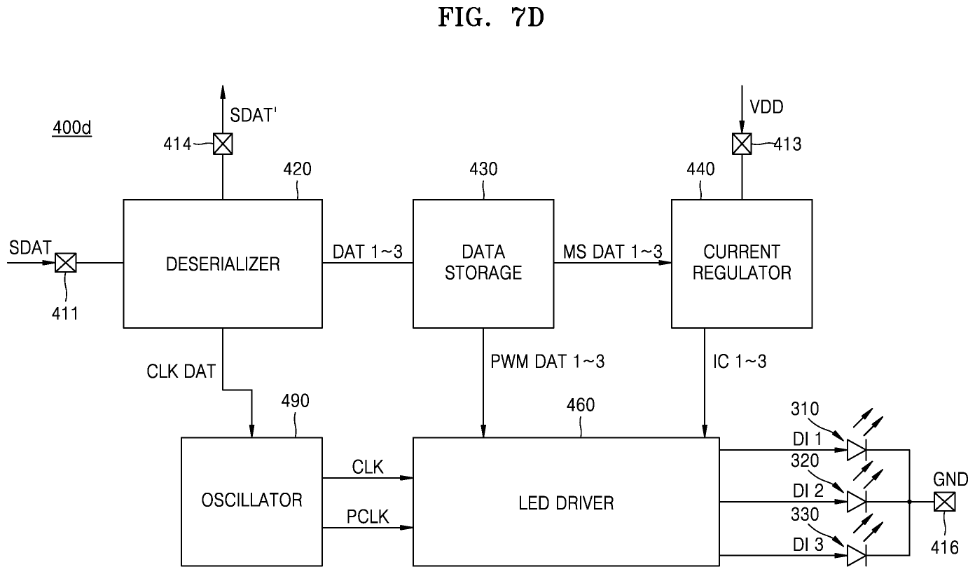

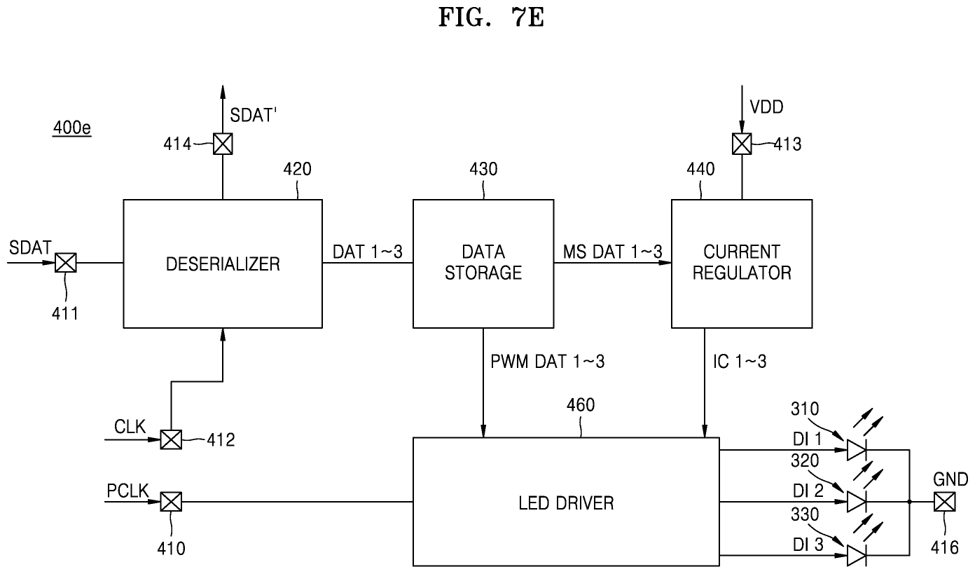

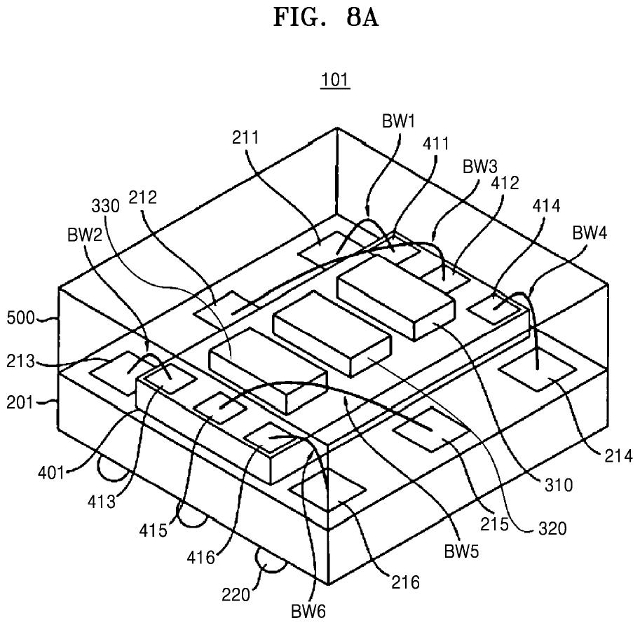

FIGS. 7A, 7B, 7C, 7D, 7E, and 7E are circuit diagrams of pixel driving integrated circuits 400a, 400b, 400c, 400d, and 400e, according to some embodiments. For convenience of description, redundant descriptions given above with reference to FIGS. 2 through 3B will be omitted, and descriptions will be focused on the differences from the above-described embodiments.

Referring to FIG. 7A, the pixel driving integrated circuit 400a may further include an electrostatic discharge (ESD) protection circuit 445 compared to the pixel driving integrated circuit 400 of FIG. 2. Except for the ESD protection circuit 445, the pixel driving integrated circuit 400a of FIG. 7A may be substantially the same as the pixel driving integrated circuit 400 of FIG. 2.

The ESD protection circuit 445 may be connected to the power pad 413. The ESD protection circuit 445 may protect elements inside the pixel driving integrated circuit 400a when a large amount of charges flow in the pixel driving integrated circuit 400a due to occurrence of an ESD event. The ESD protection circuit 445 may be further connected to the ground pad 415.

The pixel driving integrated circuit 400a may further include an ESD protection circuit connected to at least one selected from the data input pad 411, the clock pad 412, and the data output pad 414.

Referring to FIG. 7B, the pixel driving integrated circuit 400b may further include a compensator 470 compared to the pixel driving integrated circuit 400 of FIG. 2. The data storage 430 may further store characteristic data CDAT with respect to the first, second, and third LED chips 310, 320, and 330. The compensator 470 may generate at least one selected from a duty ratio control signal DCON and a current level control signal CLCON based on the characteristic data CDAT to control the first, second, and third driving currents DI 1, DI 2, and DI 3.

According to some embodiments, the compensator 470 may include a memory function. The current regulator 440 may adjust the magnitude of the first, second, and third reference currents IC 1˜3 based on the current level control signal CLCON. Accordingly, the magnitudes of the first, second, and third driving currents DI 1, DI 2, and DI 3 respectively driving the first, second, and third LED chips 310, 320, and 330 may be adjusted. The LED driver 460 may adjust the duty ratio of the first, second, and third driving currents DI 1, DI 2, and DI 3 to be suitable for the characteristic of the first, second, and third LED chips 310, 320, and 330 based on the duty ratio control signal DCON. In an embodiment, the compensator 470 may be included in the data storage 430 or in each of the current regulator 440 and the LED driver 460.

Referring to FIG. 7C, the pixel driving integrated circuit 400c may further include a detector 480 compared to the pixel driving integrated circuit 400 of FIG. 2.

When an electrical abnormality occurs in at least one of the first, second, and third LED chips 310, 320, and 330, the detector 480 may detect the electrical abnormality and generate a failure detection signal FDS. For example, the electrical abnormality may include an unintended short-circuit or opening between the first, second, and third LED chips 310, 320, and 330 and the pixel driving integrated circuit 400c.

According to some embodiments, the failure detection signal FDS may be fed back to an external controller (e.g., the controller 1400 in FIG. 10). In this case, the external controller may limit the operation of the first, second, and third LED chips 310, 320, and 330 based on the failure detection signal FDS. The pixel driving integrated circuit 400c may further include a feedback pad to provide the failure detection signal FDS to the external controller.

According to some embodiments, the failure detection signal FDS may be fed back to the data storage 430, and the data storage 430 may limit (e.g., mask) the operation of the first, second, and third LED chips 310, 320, and 330 based on the failure detection signal FDS.

According to some embodiments, the failure detection signal FDS may be fed back to the LED driver 460, and the LED driver 460 may limit the operation of the first, second, and third LED chips 310, 320, and 330 based on the failure detection signal FDS.

Referring to FIG. 7D, the pixel driving integrated circuit 400d may further include an oscillator 490, unlike the pixel driving integrated circuit 400 of FIG. 2. Accordingly, the pixel driving integrated circuit 400d does not include the clock pad 412 (in FIG. 2) and the PWM clock generator 450 (in FIG. 2).

The frame data distributed by the deserializer 420 may further include clock data CLK DAT. The oscillator 490 may generate the clock signal CLK and the PWM clock signal PCLK based on the clock data CLK DAT.

According to some embodiments, the oscillator 490 may include a ring oscillator, an RC oscillator, a crystal oscillator, or a temperature compensated crystal oscillator but is not limited thereto.

Referring to FIG. 7E, the pixel driving integrated circuit 400e may further include a clock pad 410 configured to receive the PWM clock signal PCLK, unlike the pixel driving integrated circuit 400 of FIG. 2. Accordingly, the pixel driving integrated circuit 400e does not include the PWM clock generator 450 (in FIG. 2).

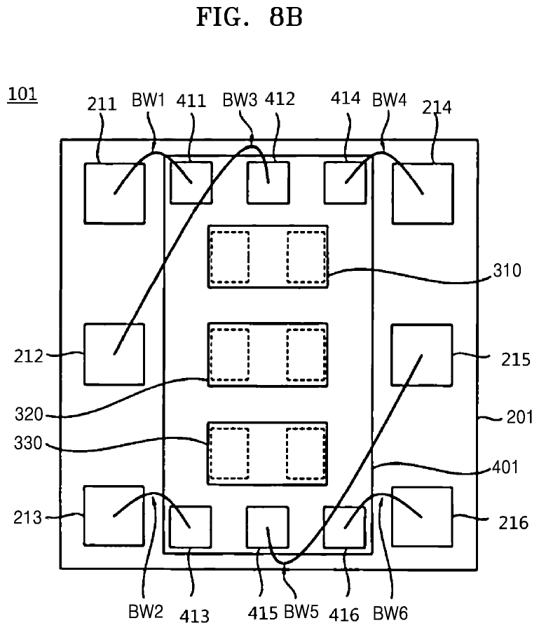

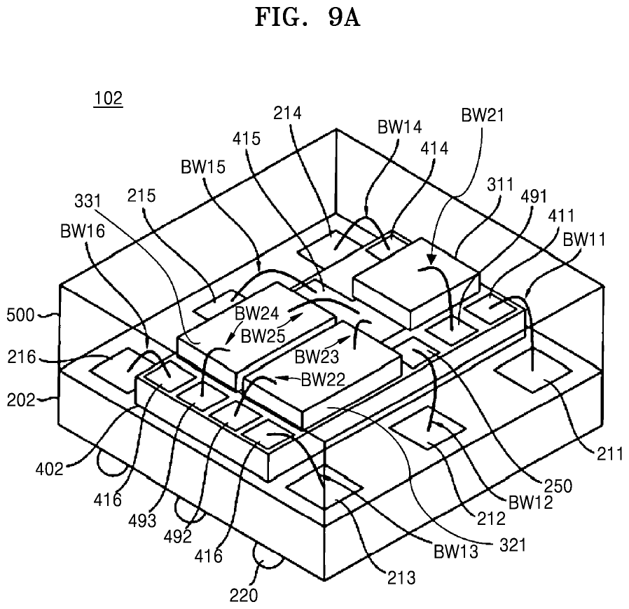

FIG. 8A is a view illustrating an LED package 101 according to some embodiments. FIG. 8B is a top view of the LED package 101 of FIG. 8A.

For convenience of description, redundant descriptions given above with reference to FIG. 1 will be omitted, and descriptions will be focused on the differences from the above-described embodiments.

Referring to FIGS. 8A and 8B, the LED package 101 may include a package substrate 201, the first, second, and third LED chips 310, 320, and 330, a pixel driving integrated circuit 401, the sealing member 500, and a plurality of bonding wires BW1, BW2, BW3, BW4, BW5, and BW6.

The package substrate 201 and the pixel driving integrated circuit 401, which are illustrated in FIGS. 8A and 8B, may be connected to each other using a wire bonding method. Unlike the package substrate 200 in FIG. 1, the package substrate 201 may include a plurality of pads 211 through 216, which are electrically connected to a plurality of pads 411 through 416, respectively, of the pixel driving integrated circuit 401 and are horizontally separated from the pixel driving integrated circuit 401. The pads of the package substrate 201 may include a data input pad 211, a clock pad 212, a power pad 213, a data output pad 214, a ground pad 215, and an auxiliary power pad 216.

Unlike the pixel driving integrated circuit 400 in FIG. 1, the pixel driving integrated circuit 401 may be electrically connected to the package substrate 201 and may include a plurality of pads on a top surface thereof (i.e., a surface of the pixel driving integrated circuit 401 opposite to a surface facing the package substrate 201). For example, the pads of the pixel driving integrated circuit 401 may include the data input pad 411, the clock pad 412, the power pad 413, the data output pad 414, the ground pad 415, and an auxiliary power pad 416.

The data input pad 211, the clock pad 212, the power pad 213, the data output pad 214, the ground pad 215, and the auxiliary power pad 216 of the package substrate 201 may be respectively connected to the data input pad 411, the clock pad 412, the power pad 413, the data output pad 414, the ground pad 415, and the auxiliary power pad 416 of the pixel driving integrated circuit 401 by the bonding wires BW1 through BW6, respectively. For example, the bonding wire BW1 may connect the data input pad 411 to the data input pad 211, the bonding wire BW2 may connect the clock pad 412 to the clock pad 212, the bonding wire BW3 may connect the power pad 413 to the power pad 213, the bonding wire BW4 may connect the data output pad 414 to the data output pad 214, the bonding wire BW5 may connect the ground pad 415 to the ground pad 215, and the bonding wire BW6 may connect the auxiliary power pad 416 to the auxiliary power pad 216.

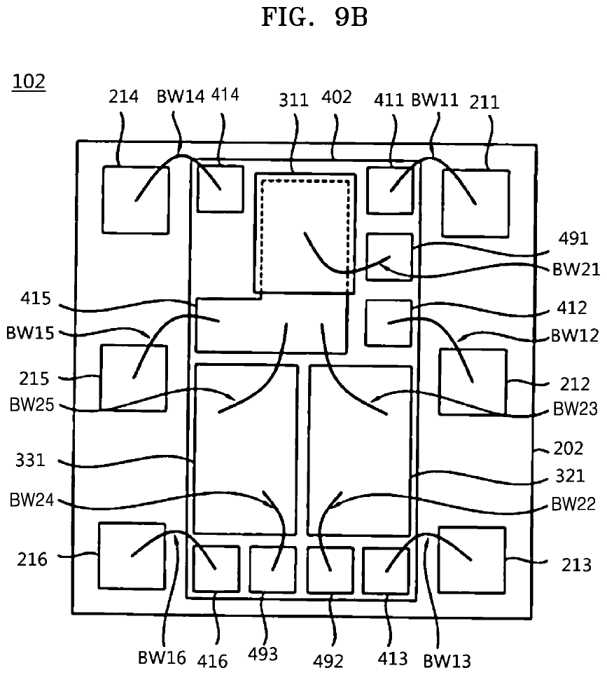

FIG. 9A is a view illustrating an LED package 102 according to some embodiments. FIG. 9B is a top view of the LED package 102 of FIG. 9A.

For convenience of description, redundant descriptions given above with reference to FIGS. 1, 8A, and 8B will be omitted, and descriptions will be focused on the differences from the above-described embodiments.

Referring to FIGS. 9A and 9B, the LED package 102 may include a package substrate 202, first, second, and third LED chips 311, 321, and 331, a pixel driving integrated circuit 402, the sealing member 500, and a plurality of bonding wires BW11, BW12, BW13, BW14, BW15, BW16, BW21, BW22, BW23, BW24, and BW25.

The package substrate 202 and the pixel driving integrated circuit 402, which are illustrated in FIGS. 9A and 9B, may be connected to each other using a wire bonding method. The first, second, and third LED chips 311, 321, and 331 may include an epi-up chip (i.e., a non-flip chip), and may thus be connected to the pixel driving integrated circuit 402 through wire bonding.

The package substrate 202 may be substantially the same as the package substrate 201 in FIGS. 8A and 8B.

Unlike the pixel driving integrated circuit 401 in FIGS. 8A and 8B, the pixel driving integrated circuit 402 may further include first, second, and third pads 491, 492, and 493 for electrical connection to the first, second, and third LED chips 311, 321, and 331, respectively.

The bonding wires BW11, BW12, BW13, BW14, BW15, and BW16 electrically connect the package substrate 202 to the pixel driving integrated circuit 402. The bonding wires BW21, BW22, BW23, BW24, and BW25 electrically connect the first, second, and third LED chips 311, 321, and 331 to the pixel driving integrated circuit 402.

The bonding wire BW21 may connect the first LED chip 311 to the first pad 491, the bonding wire BW22 may connect the second LED chip 321 to the second pad 492, the bonding wire BW24 may connect the third LED chip 331 to the third pad 493, and the bonding wires BW23 and BW25 may connect the second and third LED chips 321 and 331 to the ground pad 415. Although not shown in detail, the first LED chip 311 may be directly connected to the ground pad 415 through an electrode.

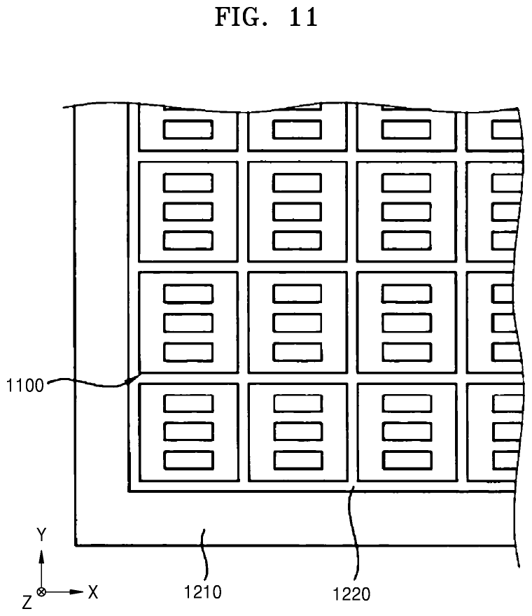

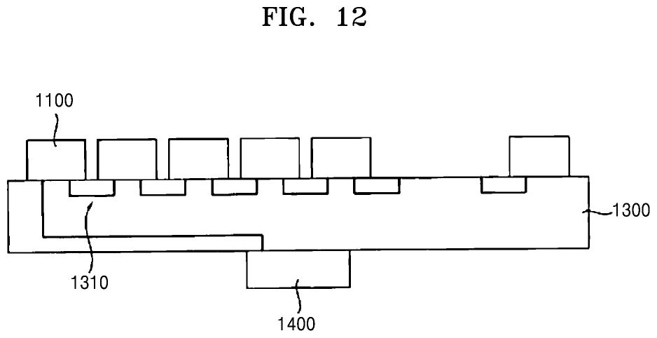

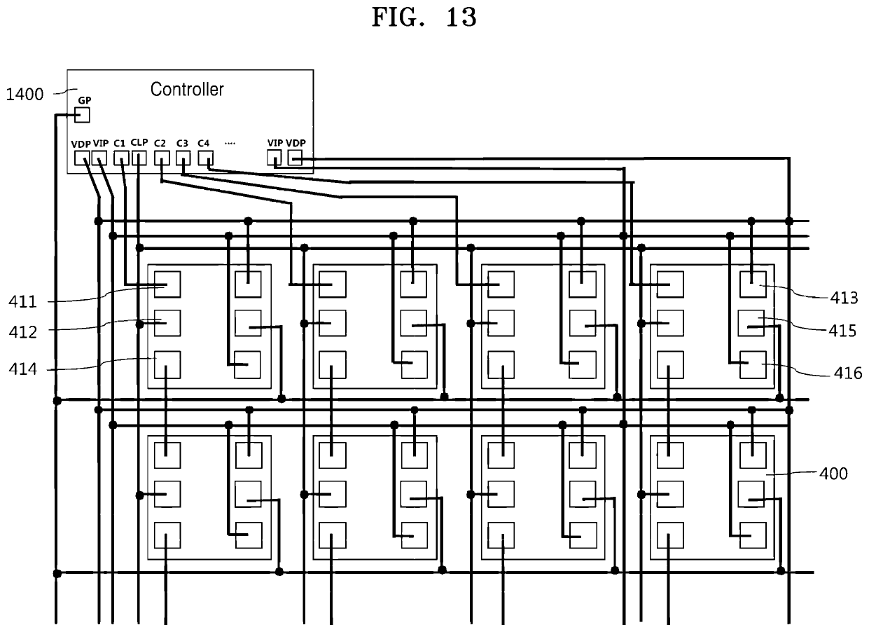

FIG. 10 is a view illustrating a display apparatus 1000 according to some embodiments. FIG. 11 is an enlarged plan view of region A in FIG. 10. FIG. 12 is a cross-sectional view of the display apparatus 1000 of FIG. 10. FIG. 13 is a circuit diagram of the display apparatus 1000.

Referring to FIG. 10, the display apparatus 1000 includes an LED module 1200 including a plurality of LED packages 1100, the PCB 1300, and the controller 1400.

The PCB 1300 is referred to as a module substrate and may include a complex inner wiring for connection between the LED packages 1100 and the controller 1400.

The LED packages 1100 may be arranged on a first surface of the PCB 1300 and may correspond to one of the LED packages 100, 101, and 102 respectively illustrated in FIGS. 1, 8A, and 9A. The LED packages 1100 may respectively form pixels of the display apparatus 1000 and may be arranged in rows and columns in X-axis and Y-axis directions on the PCB 1300. Although the display apparatus 1000 includes the LED packages 1100 arranged in a 15×15 matrix in FIG. 10, embodiments are not limited thereto. The display apparatus 1000 may include a random number and arrangement (e.g., 1024×768 or 1920×1080) of LED packages according to a resolution to be realized.

The controller 1400 is arranged on a second surface opposite to the first surface of the PCB 1300 and controls the operations of the LED packages 1100. For example, the controller 1400 may provide a signal and power for driving a pixel driving integrated circuit included in each of the LED packages 1100. Although only one controller 1400 is illustrated in FIG. 10, embodiments are not limited thereto, and a plurality of controllers may be provided on the second surface of the PCB 1300. The number of controllers may be determined based on a total number of LED packages 1100 and the number of LED packages 1100 that may be driven by one controller 1400.

Referring to FIG. 11, the display apparatus 1000 may further include a first barrier structure 1210 defining a region in which the LED packages 1100 are arranged on the PCB 1300. In addition, each of the LED packages 1100 may be surrounded by a second barrier structure 1220. The LED packages 1100 may be electrically isolated from each other by the second barrier structure 1220 and driven as individual pixels independently from each other. According to some embodiments, the first and the second barrier structures 1210 and 1220 may include a black matrix but are not limited thereto.

Referring to FIG. 12, LED packages 1100 in one row or column may be connected in series to one another through wires 1310 of the PCB 1300. Accordingly, each of the LED packages 1100 may acquire frame data only for itself among serial data transmitted from the controller 1400 and transfer remaining serial data to a subsequent one of the LED packages 1100.

Referring to FIG. 13, the controller 1400 may include input pads C1, C2, C3, C4, . . . , a clock pad CLP, a power pads VDP, a ground pad GP, and an auxiliary power pads VIP.

Each of the input pads C1, C2, C3, C4, . . . , may provide a driving signal to the input pad 411 of one of pixel driving integrated circuits 400 in different columns. The clock pad CLP may provide a clock signal to the clock pad 412 of each of the pixel driving integrated circuits 400. The power pads VDP may provide a driving current to the power pad 413 of each of the pixel driving integrated circuits 400, and a plurality of power pads VDP may be provided to prevent voltage drop. The ground pad GP may provide a ground potential to the ground pad 415 of each of the pixel driving integrated circuits 400. The auxiliary power pads VIP may provide driving power to the auxiliary power pad 416 of each of the pixel driving integrated circuits 400, and a plurality of auxiliary power pads VIP may be provided to prevent voltage drop.

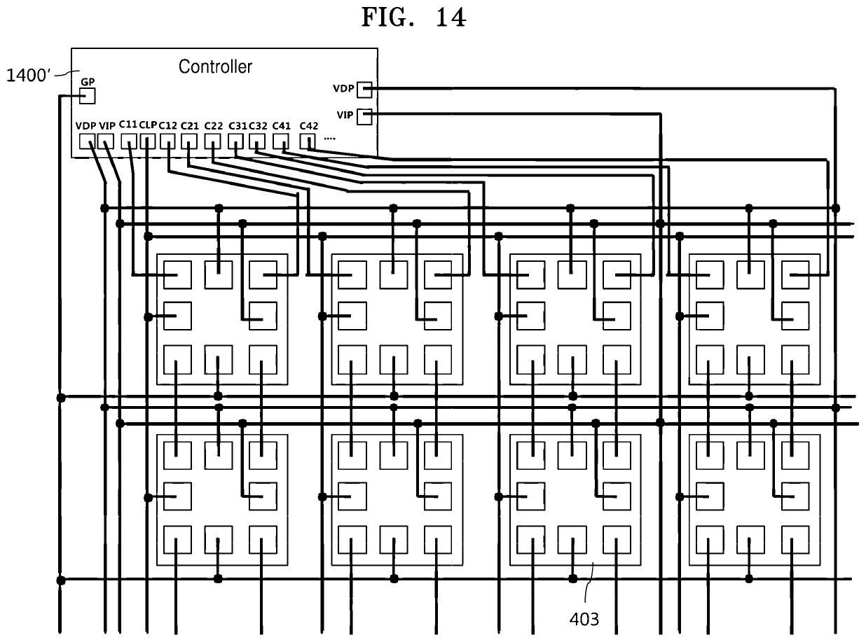

FIG. 14 is a circuit diagram of the display apparatus 1000 (of FIG. 10) according to some embodiments.

For convenience of description, redundant descriptions given above with reference to FIG. 13 will be omitted, and descriptions will be focused on the differences from the above-described embodiments.

Referring to FIG. 14, a controller 1400′ may include input pads C11, C12, C21, C22, C31, C32, C41, C42, . . . , the clock pad CLP, power pads VDP, the ground pad GP, and auxiliary power pads VIP.

As described below, each of pixel driving integrated circuits 403 may include a plurality of data input pads and a plurality of data output pads. Accordingly, a single pixel driving integrated circuit may control two pixels. For example, the input pads C11 and C12 may provide serial data to pixel driving integrated circuits 403 in a first column, the input pads C21 and C22 may provide serial data to pixel driving integrated circuits 403 in a second column, the input pads C31 and C32 may provide serial data to pixel driving integrated circuits 403 in a third column, and the input pads C41 and C42 may provide serial data to pixel driving integrated circuits 403 in a fourth column.

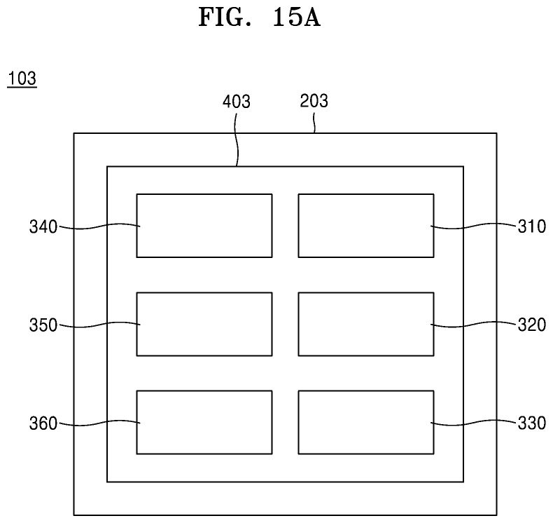

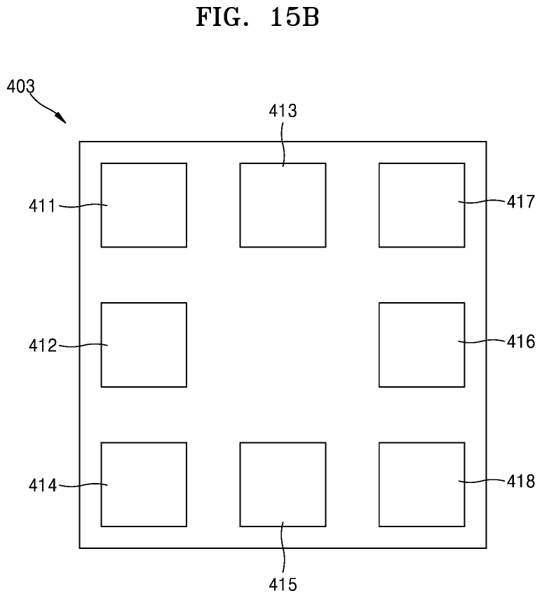

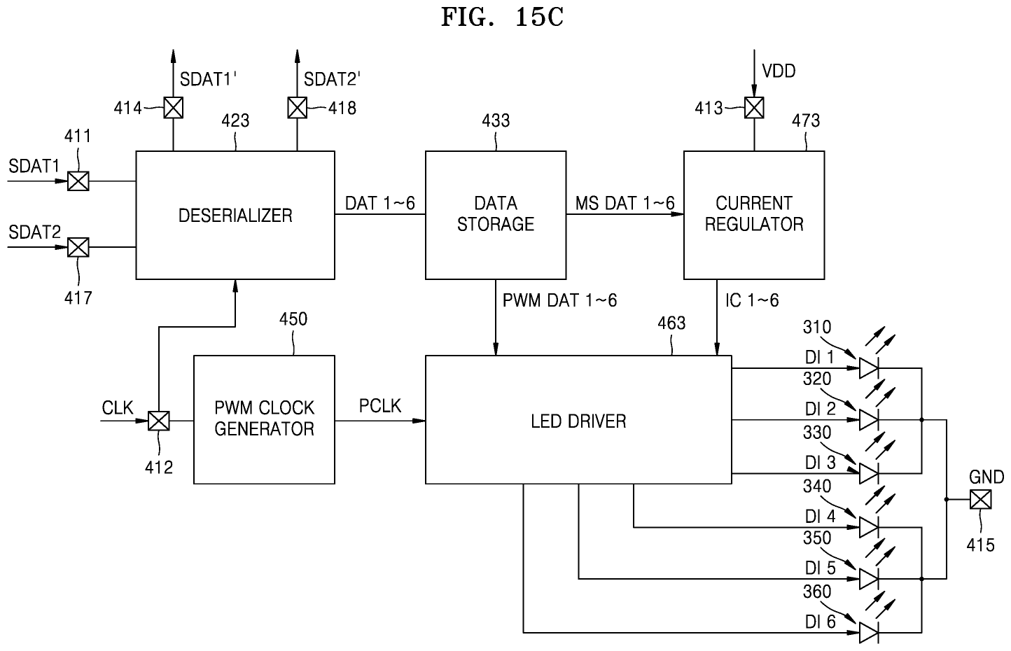

FIG. 15A is a plan view of an LED package 103 according to some embodiments. FIG. 15B is a plan view of a pixel driving integrated circuit 403 according to some embodiments and illustrates pads 411 through 418 on the back side of the pixel driving integrated circuit 403. FIG. 15C is a circuit diagram of the pixel driving integrated circuit 403 according to some embodiments.

Referring to FIG. 15A, the LED package 103 may include a package substrate 203 and the pixel driving integrated circuit 403. The package substrate 203 may be similar to the package substrate 200 in FIG. 1. The pixel driving integrated circuit 403 will be described with reference to FIGS. 15B and 15C below. Unlike the LED package 100 in FIG. 1, the LED package 103 may include six LED chips, i.e., first through sixth LED chips 310, 320, 330, 340, 350, and 360. The LED package 103 of FIG. 15A may have a 2-in-1 structure including two pixels driven by one pixel driving integrated circuit 403.

Referring to FIGS. 15B and 15C, the pixel driving integrated circuit 403 may be similar to the pixel driving integrated circuit 400 in FIG. 2 and may further include a data input pad 417 and a data output pad 418. Accordingly, a deserializer 423 may receive first serial data SDAT1 and second serial data SDAT2, extract frame data for the first through sixth LED chips 310, 320, 330, 340, 350, and 360, and distribute and output the frame data.

A data storage 433 may store the distributed frame data. For example, the data storage 433 may store driving data DAT 1˜6 respectively for the first through sixth LED chips 310, 320, 330, 340, 350, and 360 among the distributed frame data.

A current regulator 473 may receive the power supply voltage VDD through the power pad 413 and generate first through sixth reference currents IC 1˜6 based on the power supply voltage VDD and first through sixth mode select data MS DAT 1˜6. According to some embodiments, the current regulator 473 may include a current mirror.

An LED driver 463 may generate first through sixth driving currents DI 1, DI 2, DI 3, DI 4, DI 5, and DI 6, which are respectively applied to the first through sixth LED chips 310, 320, 330, 340, 350, and 360, based on the PWM clock signal PCLK, the distributed frame data (e.g., first through sixth PWM data PWM DAT 1˜6) provided from the data storage 433, and the first through sixth reference currents IC 1˜6 provided from the current regulator 473.

The first through sixth driving currents DI 1, DI 2, DI 3, DI 4, DI 5, and DI 6 may be generated based on PWM. For example, the first through sixth driving currents DI 1, DI 2, DI 3, DI 4, DI 5, and DI 6 may have first through sixth current levels respectively determined based on the first through sixth mode select data MS DAT 1˜6 and have pulse widths (e.g., on-duty times) respectively determined based on the first through sixth PWM data PWM DAT 1˜6.

Each of the first through sixth LED chips 310, 320, 330, 340, 350, and 360 may include an anode, which receives a corresponding one of the first through sixth driving currents DI 1, DI 2, DI 3, DI 4, DI 5, and DI 6 from the LED driver 463 and a cathode, which is connected to the ground pad 415 providing a ground potential GND. The first, second, and third LED chips 310, 320, and 330 may form one pixel, and the fourth through sixth LED chips 340, 350, and 360 may form another pixel.

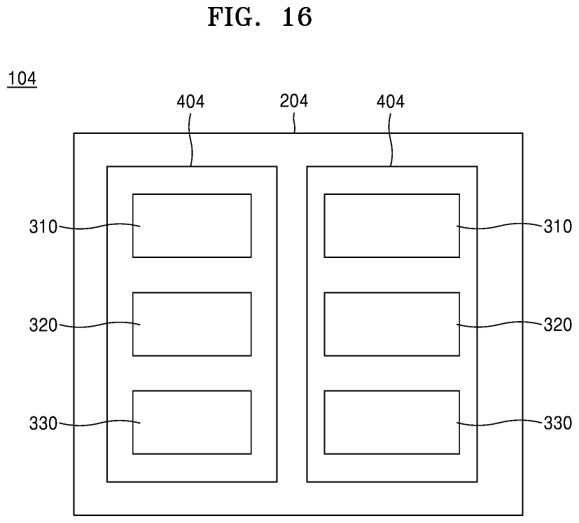

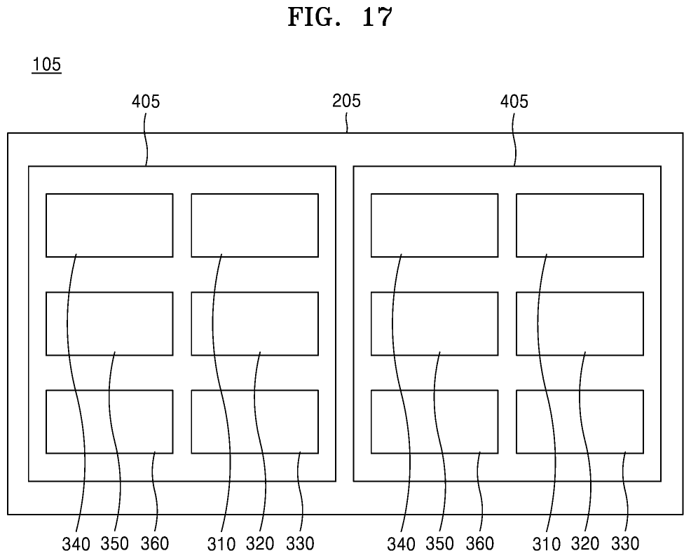

FIGS. 16 and 17 are plan views of LED packages 104 and 105 according to some embodiments.

For convenience of description, redundant descriptions given above with reference to FIG. 1 will be omitted, and descriptions will be focused on the differences from the above-described embodiments.

Referring to FIG. 16, the LED package 104 may include a package substrate 204, pixel driving integrated circuits 404, and the first, second, and third LED chips 310, 320, and 330.

The package substrate 204, the pixel driving integrated circuits 404, and the first, second, and third LED chips 310, 320, and 330 may be similar to the package substrate 200, the pixel driving integrated circuit 400, and the first, second, and third LED chips 310, 320, and 330 in FIG. 1. Unlike the LED package 100 of FIG. 1, the LED package 104 of FIG. 16 may include a plurality of pixel driving integrated circuits 404. Each of the pixel driving integrated circuits 404 may operate, as an individual pixel, the first, second, and third LED chips 310, 320, and 330 thereon. The LED package 104 may include two pixel driving integrated circuits 404, and accordingly, the LED package 104 may include two pixels.

Referring to FIG. 17, the LED package 105 may include a package substrate 205, pixel driving integrated circuits 405, and the first through sixth LED chips 310, 320, 330, 340, 350, and 360.

The package substrate 205, the pixel driving integrated circuits 405, and the first through sixth LED chips 310, 320, 330, 340, 350, and 360 may be similar to the package substrate 203, the pixel driving integrated circuit 403, and the first through sixth LED chips 310, 320, 330, 340, 350, and 360 in FIG. 15A. Unlike the package substrate 203 of FIG. 15A, the package substrate 205 of FIG. 17 may include a plurality of (e.g., two) pixel driving integrated circuits 405. Accordingly, the LED package 105 may include four pixels.

As described above with reference to FIGS. 15A through 17, a different number of pixel driving integrated circuits may be included in an LED package, and each of the pixel driving integrated circuits may drive a different number of pixels (i.e., at least three LED chips). In other words, one of skill in the art may realize an LED package, which includes M pixel driving integrated circuits (where M is an integer of at least 1) each driving N pixels (where N is an integer of at least 1), based on the description herein.

While example embodiments have been particularly shown and described, it will be understood that various changes in form and details may be made therein without departing from the spirit and scope of the following claims.

1. A display apparatus comprising:
a module substrate;
a plurality of light emitting diode (LED) packages arranged in a matrix on the module substrate; and
a controller electrically connected to the plurality of LED packages through the module substrate,
wherein each of the plurality of LED packages includes:
a package substrate;
a pixel driving integrated circuit on the package substrate; and
a first LED chip, a second LED chip, and a third LED chip on the pixel driving integrated circuit, and
wherein the pixel driving integrated circuit is configured to, based on a control signal of the controller, control a pulse width of current, applied to the first through the third LED chips at a first current level, in a first pulse width modulation (PWM) mode or control a pulse width of current, applied to the first, second, and third LED chips at a second current level, in a second PWM mode, the second current level being different from the first current level.

2. The display apparatus of claim 1, wherein each of the plurality of LED packages further includes a fourth LED chip, a fifth LED chip, and a sixth LED chip,
wherein the first, second, and third LED chips form a first pixel, and
wherein the fourth through sixth LED chips form a second pixel.

3. The display apparatus of claim 1, wherein the second current level is less than or equal to a half of the first current level.

4. The display apparatus of claim 1, wherein the second current level is about 30% to about 40% of the first current level.

5. The display apparatus of claim 1, wherein the control signal of the controller includes at least 16 bits of gray-scale data and at least one bit of mode select data, and the mode select data indicates the first PWM mode or the second PWM mode.

6. A light emitting diode (LED) package comprising:
a pixel driving integrated circuit configured to control a pixel using an active matrix; and
a first LED chip, a second LED chip, and a third LED chip on the pixel driving integrated circuit, the first, second, and third LED chips being+ configured to form the pixel,
wherein the pixel driving integrated circuit includes:
a current regulator configured to, based on frame data, output a first reference current, a second reference current, and a third reference current having variable current levels; and
an LED driver configured to generate, based on the first, second, and third reference currents and the frame data, a first driving current for driving the first LED chip, a second driving current for driving the second LED chip, and a third driving current for driving the third LED chip, and
wherein the LED driver is further configured to control a pulse width of each of the first, second, and third driving currents based on a gray scale.

7. The LED package of claim 6, wherein the frame data includes:
first mode select data, second mode select data, and third mode select data for respectively controlling magnitudes of the first, second, and third reference currents output by the current regulator; and
first pulse width modulation (PWM) data, second PWM data, and third PWM data for respectively controlling pulse widths of the first, second, and third driving currents output by the LED driver, and
each of the first, second, and third mode select data includes at least one bit.

8. The LED package of claim 7, wherein the current regulator includes:
a first control voltage generator configured to generate a first output voltage based on the at least one bit of the first mode select data; and
a first voltage controlled current source (VCCS) configured to output the first reference current based on the first output voltage.

9. The LED package of claim 8, wherein the current regulator further includes a driving transistor controlled by the first output voltage, the driving transistor including:
a gate electrode configured to receive the first output voltage;
a first electrode configured to receive a power supply voltage; and
a second electrode configured to output the first reference current.

10. The LED package of claim 9, wherein the current regulator further includes a capacitor including a third electrode and a fourth electrode, the third electrode being electrically connected to the first electrode of the driving transistor, and the fourth electrode being electrically connected to the gate electrode of the driving transistor.

11. The LED package of claim 8, wherein the current regulator further includes a first voltage regulator configured to generate at least one first input voltage based on the first mode select data, and
wherein the first control voltage generator is further configured to generate one first output voltage based on the at least one first input voltage.

12. The LED package of claim 11, wherein the first voltage regulator is further configured to generate one of the at least one first input voltage based on one bit in the first mode select data.

13. The LED package of claim 12, wherein the current regulator further includes a first digital-to-analog converter (DAC) configured to generate one first input voltage based on the at least one bit of the first mode select data, the one first input voltage being an analog voltage, and
the first voltage regulator is further configured to generate the first output voltage based on the one first input voltage.

14. A pixel driving integrated circuit for driving a pixel including light emitting diode (LED) chips, the pixel driving integrated circuit comprising:
a deserializer configured to receive serial data from an external controller and extract, from the serial data, frame data for a first pixel;
a data storage configured to store the frame data extracted by the deserializer;
a current regulator configured to output, in one of a first mode and a second mode, a first reference current, a second reference current, and a third reference current based on the frame data; and
an LED driver configured to generate, based on the frame data and the first, second, and third reference currents, a first driving current for driving a first LED chip, a second driving current for driving a second LED chip, and a third driving current for driving a third LED chip,
wherein the LED driver is further configured to control luminance of the first, second, and third LED chips by controlling pulse widths of the first, second, and third driving currents, and
wherein the current regulator is further configured to output the first, second, and third reference currents at a first current level in the first mode and output the first, second, and third reference currents at a second current level in the second mode, the second current level being lower than the first current level.

15. The pixel driving integrated circuit of claim 14, wherein the frame data includes:
first mode select data, second mode select data, and third mode select data provided to the current regulator, the first, second, and third reference currents being based on the first, second, and third mode select data, respectively; and
first pulse width modulation (PWM) data, second PWM data, and third PWM data provided to the LED driver, the first, second, and third driving currents being based on the first, second, and third PWM data, respectively.

16. The pixel driving integrated circuit of claim 15, wherein each of the first, second, and third mode select data includes at least one bit.

17. The pixel driving integrated circuit of claim 15, wherein each of the first, second, and third PWM data includes at least 16 bits.

18. The pixel driving integrated circuit of claim 15, wherein the LED driver is further configured to control such that a unit emitting time and a frame time satisfy the formula below, the unit emitting time corresponding to a minimum emitting time of the first, second, and third LED chips, and the frame time corresponding to a time of one frame of the first, second, and third LED chips:
$$\frac{( frame time )}{{2}^{n}} < ( unit emitting time )$$
where “n” is a number of bits in each of the first, second, and third PWM data.

19. The pixel driving integrated circuit of claim 15, wherein the LED driver is further configured to control such that a unit emitting time and a frame time satisfy the formula below, the unit emitting time corresponding to a minimum emitting time of the first, second, and third LED chips, and the frame time corresponding to a time of one frame of the first, second, and third LED chips:
$$N \times \frac{( frame time )}{{2}^{n}} = ( unit emitting time )$$
where “n” is a number of bits in each of the first, second, and third PWM data, and N is an integer of at least 2.

20. The pixel driving integrated circuit of claim 19, wherein the LED driver is further configured to control such that the unit emitting time and a period of a PWM clock signal satisfy the formula below:
(unit emitting time)=N×(a period of a PWM clock signal)

21. (canceled)

22. (canceled)
